(19) United States
(12) Patent Application Publication
(10) Pub. No.: US 2016/0072071 A1
(43) Pub. Date: Mar. 10, 2016

(54) Photoelectric Conversion Element, Photoelectric Conversion Element Having Storage/Discharge Function, and Secondary Battery

(71) Applicant: SELMO ENTERTAINMENT JAPAN, Kasugai-shi (JP)

(72) Inventor: Shinichiro Yumura, Tokyo (JP)

(21) Appl. No.: 14/782,943

(22) PCT Filed: Apr. 11, 2014
(86) PCT No.: PCT/JP2014/060474

§ 371 Date: Oct. 7, 2015

(30) Foreign Application Priority Data
Apr. 12, 2013 (JP) 2013-084049
Apr. 12, 2013 (JP) 2013-084050
Apr. 12, 2013 (JP) 2013-084051

(51) Int. Cl. H01L 51/00; H01M 4/583; H01M 4/48; H02S 40/38; H01M 10/0568; H01M 10/0565; H01M 10/46; H01L 51/42; H01M 4/38

(52) U.S. Cl. CPC H01L 51/0046; H01L 51/4293; H01L 51/0048; H01L 51/4213; H01L 51/0036; H01L 51/0035; H01L 51/0078; H01L 51/0097; H01L 51/0047; H01M 4/583; H01M 4/48; H01M 4/38; H01M 10/0568; H01M 10/0565; H01M 10/46; H02S 40/38

(57) ABSTRACT

A photoelectric conversion element having storage/discharge ability has a substrate layer that is formed of a conductive metal and is connected to a minus electrode of output electrodes, a collector electrode that is formed by being joined to one surface of the substrate layer, an n-type compound semiconductor layer that is formed of a dielectric composition containing a fullerene and is formed by being connected to the collector electrode, a p-type compound semiconductor layer that is formed in contact with the n-type compound semiconductor layer, and a pn-bulk layer that is formed between the n-type compound semiconductor layer and the p-type compound semiconductor layer and is intermittently in contact with the n-type compound semiconductor layer and the p-type compound semiconductor layer, and has a secondary battery arranged on the other surface of the substrate layer to provide a storage/discharge function. Also provided is the secondary battery preferably used herein.

### TECHNICAL FIELD

The present invention relates to a photoelectric conversion element utilizing fullerenes, a photoelectric conversion element having a storage/discharge function and a secondary battery which can be preferably used for the photoelectric conversion element utilizing fullerenes.

### BACKGROUND ART

With changes of energy sources, photoelectric conversion elements (solar batteries) have been recently noted. The photoelectric conversion elements have various advantages such that they have no drive part and rarely break down because they produce electrical energy directly from sunlight, and there is no limitation on the installation location provided that it is a place in the light. Therefore, instances in which the photoelectric conversion elements are installed on the roofs of individual houses or on the rooftops of buildings are increasing.

In the photoelectric conversion elements, however, there are various problems such that power generation cannot be carried out in the nighttime of no sunlight irradiation, the power generation quantity varies depending upon the weather, weight reduction is limited because silicon wafer is generally used as an electrode, impartation of flexibility is extremely difficult because silicon wafer is used, and arrangement on a curved surface is difficult. Moreover, it is also a problem that the conversion efficiency to convert light into electricity is low.

Thus, the photoelectric conversion elements have come into use particularly as solar batteries, but they are used involving such problems as above.

Accordingly, such problems as above should be solved as soon as possible. As photoelectric conversion elements which can be mass-produced inexpensively and use lightweight organic semiconductors among the photoelectric conversion elements, those of dye-sensitized type, bulk hetero type, hetero-pn-junction type, Schottky type, etc. have been proposed (Japanese Translation of PCT International Application Publication No. JP-T-1996-500701, patent literature 1).

The present invention is a photoelectric conversion element most similar to the heterojunction type photoelectric conversion element among these photoelectric conversion elements.

The heterojunction type photoelectric conversion element utilizes charge transfer caused by photoinduction at the bonded interface of a laminate consisting of a layer formed of an electron donor and a layer formed of an electron acceptor. For example, in the heterojunction, a layer formed of an electron donor and a layer formed of an electron acceptor are laminated together, and charge transfer caused by photoinduction at the bonded interface of the laminate is used. For example, in Japanese Patent Laid-Open Publication No. 2003-304014 (patent literature 2), a solar battery which uses copper phthalocyanine as an electron donor, uses a perylene derivative as an electron acceptor and has attained a conversion efficiency of 1% has been reported. In addition, condensed aromatic compounds such as pentacene and tetracene have been studied as electron donors, and fullerenes such as C₆₀ fullerene have been studied as electron acceptors.

However, these photoelectric conversion elements have low conversion efficiency and are not suitable for practical use.

In WO 2007-126102 (patent literature 3), it is described that when an organic pigment is compounded, an organic pigment precursor is used in order to increase solubility, but specific constitution of a photoelectric conversion element is not described in detail.

### CITATION LIST

### Patent Literature

Patent literature 1: Japanese Translation of PCT International Application Publication No. JP-T-1996-500701

Patent literature 2: Japanese patent Laid-Open Publication No. 2003-304014

Patent literature 3: WO 2007-126102

Patent literature 4: U.S. Pat. No. 6,071,989

### SUMMARY OF INVENTION

### Technical Problem

It is an object of the present invention to provide a novel photoelectric conversion element capable of efficiently converting optical energy into electrical energy by using fullerenes.

In particular, it is an object of the present invention to provide a photoelectric conversion element capable of converting not only visible light but also infrared rays and far infrared rays into electrical energy.

Further, it is an object of the present invention to provide a photoelectric conversion element which can be operated not only in the daytime but also in the nighttime by incorporating a secondary battery in a photoelectric conversion element though operation of conventional photoelectric conversion elements is limited to the daytime of a fine day and which can undergo power generation even by infrared rays including far infrared rays.

It is also an object of the present invention to provide a novel photoelectric conversion element capable of efficiently converting optical energy into electrical energy by using fullerenes.

In particular, it is an object of the present invention to provide a photoelectric conversion element capable of converting not only visible light but also infrared rays and far infrared rays into electrical energy.

Moreover, it is an object of the present invention to provide a secondary battery which is preferably used in combination with a photoelectric conversion element capable of efficiently converting optical energy into electrical energy by using fullerenes.

In particular, it is an object of the present invention to provide a secondary battery which is united to a photoelectric conversion element, can efficiently store power generated by the photoelectric conversion element capable of converting not only visible light but also infrared rays and far infrared rays into electrical energy, and can discharge power in the nighttime or the like in which the power generation quantity is small.

That is to say, it is also an object of the present invention to provide a secondary battery which can be preferably used in a photoelectric conversion element having a storage/discharge function and having specific constitution.

### Solution to Problem

The photoelectric conversion element of the present invention is a photoelectric conversion element having a substrate layer that is formed of a conductive metal and is connected to a minus electrode of output electrodes, a collector electrode that is formed by being joined to one surface of the substrate layer, an n-type compound semiconductor layer that is formed of a dielectric composition containing a fullerene and is formed by being connected to the collector electrode, a p-type compound semiconductor layer that is formed in contact with the n-type compound semiconductor layer, a pn-bulk layer that is formed between the n-type compound semiconductor layer and the p-type compound semiconductor layer and is intermittently in contact with the n-type compound semiconductor layer and the p-type compound semiconductor layer, and a plus electrode that is formed on the other surface of the substrate layer through an insulating layer, wherein the plus electrode is insulated from the collector electrode, the pn-bulk layer and the n-type compound semiconductor layer but is electrically connected to the p-type compound semiconductor layer.

In the photoelectric conversion element of the present invention, the n-type compound semiconductor layer is preferably formed on a surface of the collector electrode through at least one layer selected from the group consisting of a graphene layer, a graphite layer and a carbon nanotube layer.

In the photoelectric conversion element of the present invention, it is preferable that the dielectric composition containing a fullerene and forming the n-type compound semiconductor layer contains at least C₆₀ fullerene and/or C₇₀ fullerene, a conductive polymer and an organic pigment, and at least a part of them are bonded to one another to make electron transfer in the n-type compound semiconductor layer possible.

In the photoelectric conversion element of the present invention, it is preferable that at least a part of the fullerene that forms the n-type compound semiconductor layer is contained in the n-type compound semiconductor layer in such a manner that it is capable of molecular rotation.

In the photoelectric conversion element of the present invention, the p-type compound semiconductor layer is preferably a transparent evaporated film formed from an oxide comprising silicon dioxide containing a dopant that forms a positive hole.

In the photoelectric conversion element of the present invention, the substrate layer is preferably formed from copper.

In the photoelectric conversion element of the present invention, the collector electrode is preferably formed of a metallic aluminum evaporated layer.

In the photoelectric conversion element of the present invention, the pn-bulk layer is preferably a ferroelectric layer containing at least one ferroelectric selected from the group consisting of lead titanate, lead(II) zirconate titanate and strontium titanate.

In the photoelectric conversion element of the present invention, the fullerene is preferably at least one fullerene selected from the group consisting of C₆₀, C₆₂, C₆₈, C₇₀, C₈₀, C₈₂ and carbon nanotube (CNT), or any of the fullerenes, which has been doped or intercalated with an alkali metal and/or an alkaline earth metal, or any of the fullerenes, which includes a metal.

In the photoelectric conversion element of the present invention, it is preferable that the fullerene contained in the n-type compound semiconductor layer is in contact with the pn-bulk layer while vibrating, and the photoelectric conversion element is a photoelectric conversion element utilizing also electromotive force generated by a piezoelectric effect due to the vibration contact with the pn-bulk layer.

The photoelectric conversion element of the present invention is preferably a photoelectric conversion element utilizing also electromotive force generated by a Seebeck effect attributable to a difference in temperature between the negative electrode on a panel front surface and the positive electrode on a panel back surface.

The photoelectric conversion element having storage/discharge ability of the present invention is a photoelectric conversion element having storage/discharge ability, which has a substrate layer that is formed of a conductive metal and is connected to a minus electrode of output electrodes, a collector electrode that is formed by being joined to one surface of the substrate layer, an n-type compound semiconductor layer that is formed of a dielectric composition containing a fullerene and is formed by being connected to the collector electrode, a p-type compound semiconductor layer that is formed in contact with the n-type compound semiconductor layer, and a pn-bulk layer that is formed between the n-type compound semiconductor layer and the p-type compound semiconductor layer and is intermittently in contact with the n-type compound semiconductor layer and the p-type compound semiconductor layer, wherein

a secondary battery is arranged on the other surface of the substrate layer,

the secondary battery is formed while including the collector electrode and the substrate layer, and has a secondary battery minus electrode face laminated on the other surface of the substrate layer, said secondary battery minus electrode face being formed if necessary, a ferroelectric layer laminated on the secondary battery minus electrode face, a solid electrolyte layer, an ion supply substance layer formed through the solid electrolyte layer, a secondary battery plus electrode face that is formed of at least one conductive material selected from the group consisting of C₆₀ fullerene, C₇₀ fullerene, graphene, graphite and carbon nanotube (CNT) and is laminated in contact with the ion supply substance layer, said secondary battery plus electrode face being formed if necessary, and a plus electrode of output electrodes of the secondary battery, said plus electrode being connected to the p-type compound semiconductor layer.

That is to say, the photoelectric conversion element of the present invention can be used as a photoelectric conversion element having storage/discharge ability by combining it with a secondary battery.

In the photoelectric conversion element having storage/discharge ability of the present invention, the ferroelectric layer and the ion supply substance layer preferably contain an ion supply component.

In the photoelectric conversion element having storage/discharge ability of the present invention, the n-type compound semiconductor layer is preferably formed on a surface of the collector electrode through at least one layer selected from the group consisting of a graphene layer, a graphite layer and a carbon nanotube layer.

In the photoelectric conversion element having storage/discharge ability of the present invention, it is preferable that at least a part of the fullerene that forms the n-type compound semiconductor layer is contained in the n-type compound semiconductor layer in such a manner that it is capable of molecular rotation.

In the photoelectric conversion element having storage/discharge ability of the present invention, the ion supply substance layer can contain at least one nonaqueous electrolyte selected from the group consisting of a cationic polymer electrolyte and a fullerene electrolyte in addition to an ionic liquid electrolyte.

In the photoelectric conversion element having storage/discharge ability of the present invention, the n-type compound semiconductor layer is preferably formed on a surface of the collector electrode through at least one layer selected from the group consisting of a graphene layer, a graphite layer and a carbon nanotube layer.

In the photoelectric conversion element having storage/discharge ability of the present invention, the dielectric composition containing a fullerene and forming the n-type compound semiconductor layer preferably contains at least C₆₀ fullerene and/or C₇₀ fullerene, a conductive polymer and an organic pigment.

It is preferable that the fullerene for use in the present invention comprises C₆₀ fullerene and/or C₇₀ fullerene, at least a part of them are bonded to one another to make electron transfer in the n-type compound semiconductor layer possible, and at least apart of the fullerene that forms the n-type compound semiconductor layer is contained in the n-type compound semiconductor layer in such a manner that it is capable of molecular rotation.

In the photoelectric conversion element having storage/discharge ability of the present invention, the p-type compound semiconductor layer is preferably a transparent evaporated film formed from an oxide comprising silicon dioxide containing a dopant that forms a positive hole.

In the photoelectric conversion element having storage/discharge ability of the present invention, the substrate layer is preferably formed from copper.

In the photoelectric conversion element having storage/discharge ability of the present invention, the collector electrode is preferably formed of a metallic aluminum evaporated layer.

In the photoelectric conversion element having storage/discharge ability of the present invention, the pn-bulk layer is preferably a ferroelectric layer containing at least one dielectric selected from the group consisting of lead titanate, lead(II) zirconate titanate and strontium titanate.

In the photoelectric conversion element having storage/discharge ability of the present invention, the fullerene is preferably at least one fullerene selected from the group consisting of C₆₀, C₆₂, C₆₈, C₇₀, C₈₀, C₈₂ and carbon nanotube (CNT), or any of the fullerenes, which has been doped or intercalated with an alkali metal and/or an alkaline earth metal, or any of the fullerenes, which includes a metal.

In the photoelectric conversion element having storage/discharge ability of the present invention, it is preferable that the fullerene contained in the n-type compound semiconductor layer is in contact with the pn-bulk layer while vibrating, and the photoelectric conversion element is a photoelectric conversion element utilizing also electromotive force generated by a piezoelectric effect due to the vibration contact with the pn-bulk layer.

The photoelectric conversion element having storage/discharge ability of the present invention is preferably a photoelectric conversion element utilizing also electromotive force generated by a Seebeck effect attributable to a difference in temperature between the negative electrode on a panel front surface and the positive electrode on a panel back surface.

In the photoelectric conversion element having storage/discharge ability of the present invention, the secondary battery minus electrode face is preferably formed of silicon dioxide doped or intercalated with at least one atom selected from the group consisting of phosphorus, boron and fluorine.

In the photoelectric conversion element having storage/discharge ability of the present invention, it is preferable that the ferroelectric layer and the ion supply substance layer contain an ionic liquid, and the ionic liquid is at least one ionic liquid selected from the group consisting of

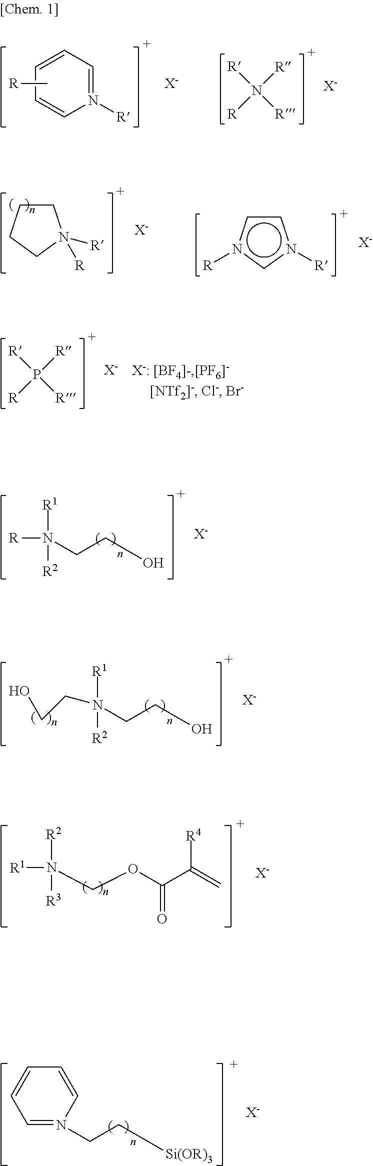

wherein R, R¹, R², R³, R′, R″ and R′″ each independently represent a hydrogen atom or an alkyl group, and each n independently represents an integer of 1 to 3.

The secondary battery of the present invention is a secondary battery comprising a secondary battery minus electrode face that is formed of a metal oxide comprising silicon dioxide and is laminated on one surface of a substrate layer having an evaporated collector electrode on the other surface, a ferroelectric layer that contains an ionic liquid electrolyte and is laminated on the secondary battery minus electrode face, a solid electrolyte layer, an ion supply substance layer that contains an ionic liquid electrolyte and is formed through the solid electrolyte layer, a secondary battery plus electrode face that is formed of at least one conductive material selected from the group consisting of C₆₀ fullerene, C₇₀ fullerene, graphene, graphite and carbon nanotube (CNT) and is laminated in contact with the ion supply substance layer, and a plus electrode that is arranged by being connected to the secondary battery plus electrode face, wherein a minus electrode terminal is derived from the substrate layer, and a plus electrode terminal is derived from the plus electrode.

The first nonaqueous electrolyte layer in the secondary battery of the present invention can contain at least one nonaqueous electrolyte selected from the group consisting of an anion molecule electrolyte and a fullerene electrolyte

The second nonaqueous electrolyte layer in the secondary battery of the present invention can contain at least one nonaqueous electrolyte selected from the group consisting of a cationic polymer electrolyte and a fullerene electrolyte

In the secondary battery of the present invention, it is preferable that the ferroelectric layer and the ion supply substance layer each independently further contain at least one nonaqueous electrolyte selected from the group consisting of a cationic polymer electrolyte, an anion molecule electrolyte and a fullerene electrolyte.

In the secondary battery of the present invention, the substrate layer is preferably formed from copper.

In the secondary battery of the present invention, the collector electrode is preferably formed of a metallic aluminum evaporated layer.

In the secondary battery of the present invention, the fullerene is preferably at least one fullerene selected from the group consisting of C₆₀, C₆₂, C₆₈, C₇₀, C₈₀, C₈₂ and carbon nanotube (CNT), or any of the fullerenes, which has been doped or intercalated with an alkali metal and/or an alkaline earth metal, or any of the fullerenes, which includes a metal.

In the secondary battery of the present invention, the solid electrolyte layer is preferably a reverse osmosis membrane.

In the secondary battery of the present invention, it is preferable that the ion supply substance layer contains an ion supply substance, and the ionic liquid is at least one ionic liquid selected from the group consisting of

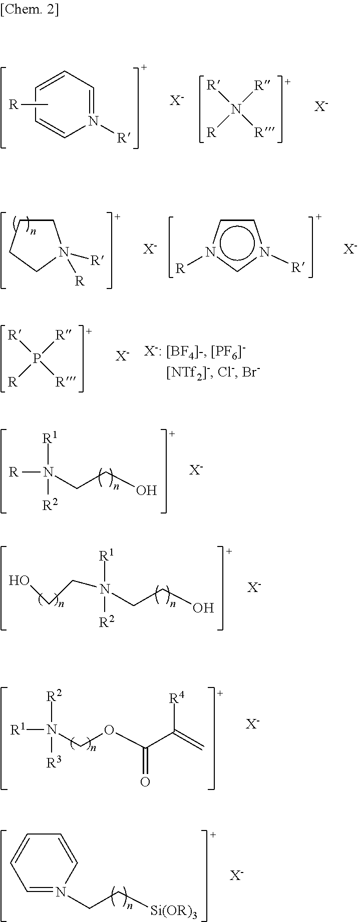

wherein R, R¹, R², R³, R′, R″ and R′″ each independently represent a hydrogen atom or an alkyl group, and each n independently represents an integer of 1 to 3.

In the secondary battery of the present invention, the ion supply substance is preferably a halide of an alkali metal.

In the secondary battery of the present invention, it is preferable that the ferroelectric layer and the ion supply substance layer contain a fullerene electrolyte, the ferroelectric layer is doped or intercalated with at least one component selected from the group consisting of chlorine, iodine and bromine, and the ion supply substance layer is doped or intercalated with phosphorus and/or boron.

### Advantageous Effects of Invention

The photoelectric conversion element of the present invention contains a fullerene, a conductive polymer and an organic pigment in the n-type compound semiconductor layer, and when the photoelectric conversion element is irradiated with visible light or infrared light, the light is absorbed by the organic pigment to excite the organic pigment, and charge separation occurs in the conductive polymer. This charge separation state is taken over to the fullerene that is connected to the conductive polymer, and the excited minus charge is accumulated in the substrate layer that is a minus electrode, through the collector electrode, while positive holes generated in the p-type compound semiconductor layer are accumulated in the plus electrode 22 through the conductive metal 26, whereby a potential difference is produced between the plus electrode 22 and the substrate layer 12 that is a minus electrode. Therefore, by virtue of irradiation with light, the photoelectric conversion element 10 shown in FIG. 1 functions as a solar battery.

The photoelectric conversion element having storage/discharge ability of the present invention roughly has constitution wherein such a photoelectric conversion element as above and a secondary battery are united. Owing to minus charge produced by driving of the photoelectric conversion element, the secondary battery minus electrode face 42 of the storage battery arranged on the back surface of the substrate layer 12 and the ferroelectric layer 44 are negatively charged, and parting by the solid electrolyte layer, the second electrolyte layer 48 and the secondary battery plus electrode face 50 are positively charged. As a result, power generated in the photoelectric conversion element of the present invention is stored in the secondary battery arranged on the back surface. On the other hand, when the photoelectric conversion element of the present invention cannot generate power in the nighttime or the like, power having been stored in the secondary battery arranged on the back surface of this photoelectric conversion element is discharged, so that even in circumstances where the photoelectric conversion element cannot generate power, power can be supplied by the power discharge from the secondary battery.

Since the secondary battery for use in the present invention has a ferroelectric layer and an ion supply substance layer and does not use any water-soluble electrolytic solution, storage/discharge can be efficiently carried out, and besides, liquid leakage extremely hardly takes place, so that this secondary battery can be used over a long period of time. Moreover, the secondary battery is capable of discharging electricity while storing electricity, and by driving the photoelectric conversion element in the daytime with a small quantity of solar irradiation and in the nighttime, electricity can be charged while being generated and a shortage can be discharged.

When the photoelectric conversion element is irradiated with visible light or infrared light, the light is absorbed by the organic pigment to excite the organic pigment, and charge separation occurs in the conductive polymer, and by the connection of the conductive polymer, each cell of the secondary battery of the present invention can store and discharge power having been generated in the photoelectric conversion element.

That is to say, the secondary battery is almost united to the photoelectric conversion element and stores power generated in the photoelectric conversion element, and besides, in circumstances where the photoelectric conversion element cannot generate power, such as the nighttime, the secondary battery discharges power having been stored.

Therefore, the photoelectric conversion element incorporating the secondary battery of the present invention can stably supply power regardless of daytime, nighttime, quantity of solar irradiation, etc.

The photoelectric conversion element having storage/discharge ability of the present invention has constitution wherein such a photoelectric conversion element as above and a secondary battery are united. Owing to minus charge produced by driving of the photoelectric conversion element, the secondary battery minus electrode face 42 of the storage battery arranged on the back surface of the substrate layer 12 and the ferroelectric layer 44 are negatively charged, and parting by the solid electrolyte layer, the second electrolyte layer 48 and the secondary battery plus electrode face 50 are positively charged. As a result, power generated in the photoelectric conversion element of the present invention is stored in the secondary battery arranged on the back surface. On the other hand, when the photoelectric conversion element of the present invention cannot generate power in the nighttime or the like, power having been stored in the secondary battery arranged on the back surface of this photoelectric conversion element is discharged, so that even in circumstances where the photoelectric conversion element cannot generate power, power can be supplied by the discharge from the secondary battery.

### BRIEF DESCRIPTION OF DRAWINGS

FIG. 1 is a view showing an example of a section of the photoelectric conversion element of the present invention.

FIG. 2 is a view showing an example of a section of a photoelectric conversion element having storage/discharge ability, in which the photoelectric conversion element of the present invention and a secondary battery are combined.

FIG. 3 is a view showing an example of a section of a secondary battery which can be used in the present invention.

FIG. 4 is a graph showing an example of an absorption wavelength region of the photoelectric conversion element of the present invention.

FIG. 5 is a graph showing an example of discharge property of a secondary battery which can be used in the present invention.

FIG. 6 is a sectional view showing an example of a thermoelectromagnetic wave power generation element produced in Example 1 of the present invention.

FIG. 7 is an IV curve of a 5 mm×5 mm cell.

FIG. 8 is an SEM photograph (20000 magnifications) of p-type semiconductor polymer material (polyaniline, graphene) particles.

FIG. 9 is an SEM photograph (40000 magnifications) of n-type nanocarbon material (C₆₀ fullerene, graphene, H₂Pc, molybdenum oxide) particles.

FIG. 10 is an SEM photograph showing an example of a sheet of graphene that is a conductive assistant used in the p-type organic semiconductor layer and the n-type organic semiconductor layer. This graphene sheet has a maximum size of 40 μm (width)×120 μm (height) (3000 magnifications).

FIG. 11 is a sectional view showing an example of the secondary battery of the present invention.

FIG. 12 is a graph showing an example of property of the secondary battery of the present invention.

FIG. 13 is a schematic sectional view of a photoelectric conversion element in the working example of a power generation element having a power generation layer and a power storage layer.

FIG. 14 is an IV curve of a 5 mm×5 mm cell of a storage effect power generation element obtained in Example 3.

### DESCRIPTION OF EMBODIMENTS

Next, the photoelectric conversion element of the present invention and the secondary battery are described in detail with reference to the attached drawings and the working examples.

[Photoelectric Conversion Element]

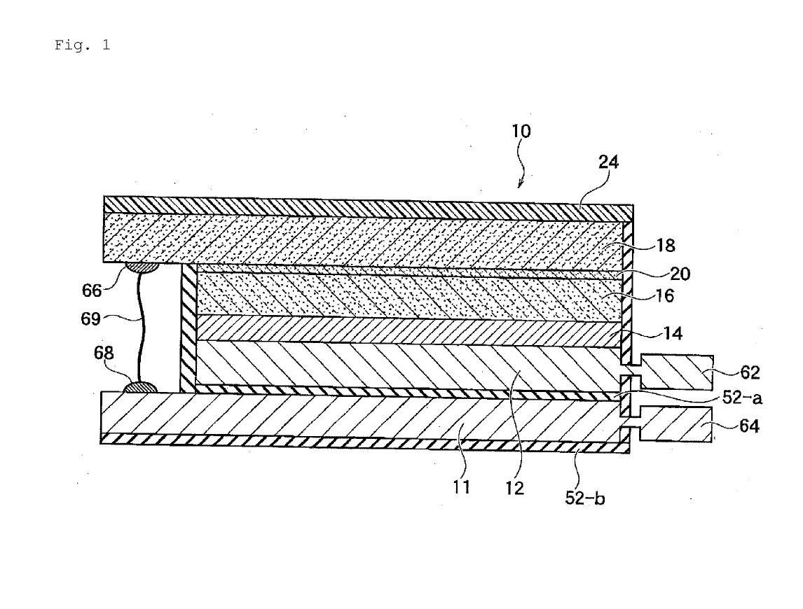

As shown in FIG. 1, the photoelectric conversion element 10 of the present invention has a plus electrode terminal 64 at one end, a bump 68 formed on the upper surface of the other end, and a plus electrode 11 whose front and back surfaces have been coated with insulators.

In the present working example, the plus electrode 11 was formed from a copper foil having a thickness of 50 μm. Although this plus electrode can be formed not only from copper foil but also from silver, gold or alloys thereof, it is preferable to use a copper plate having the above thickness from the viewpoint of cost. The thickness of the plus electrode 11 can be usually set within the range of 8 to 75 μm.

The plus electrode 11 was coated with insulating layers 52-a and 52-b each having a thickness of 20 μm. Although the thickness of the insulating layers 52-a and 52-b is not specifically restricted, it is usually in the range of 1 to 50 μm.

The insulating layers 52-a and 52-b were formed from an epoxy resin having insulating property. The insulating layers 52-a and 52-b can be formed from a nonmetal having no conduction property, an insulating resin or the like, and since they are heated in the later step, it is preferable to form the layers from thermosetting resins having high heat resistance, such as epoxy resin, polyimide resin and resol type phenolic resin.

On a surface of the insulating layer 52-a, a substrate layer 12 made of copper and having a thickness of 2 μm was formed by using a copper foil or a metal deposition method. From one end of the substrate layer, a minus electrode terminal 62 was derived.

The substrate layer 12 and the minus electrode terminal 62 were usually formed of the same conductive metal, and as the conductive metal for forming the substrate layer 12, copper, silver, gold or the like can be used, but it is preferable to use copper of the above thickness from the viewpoint of cost. The thickness of the substrate layer 12 can be usually set in the range of 0.1 to 10 μm. The substrate layer 12 of the above thickness is difficult to handle, and therefore, a laminate in which a releasable support is arranged on one surface of the substrate layer can be also used. The substrate layer 12 can be formed by using a copper plate, electroless plating, deposition or the like, and when a copper plate is used, a copper foil having a thickness in the range of 1 to 10 μm is preferably used from the viewpoint of handling. When the substrate layer 12 is formed by electroless plating or deposition, the thickness of the substrate layer 12 is preferably in the range of 0.1 to 0.3 μm. For the electroless plating, an electroless plating solution for copper, which is usually on the market, can be used. When the substrate layer is formed by deposition, deposition methods such as CVD, vacuum deposition and sputtering can be adopted, but in the present invention, the substrate layer 12 is preferably formed by sputtering or vacuum deposition. When a deposition method such as vacuum deposition is adopted, it is preferable to deposit a substrate layer-forming metal under reduced pressure in an atmosphere of an inert gas such as nitrogen gas or argon gas while heating the metal to a temperature of not lower than the melting temperature of the metal. The minus electrode terminal 62 derived from the substrate layer 12 can be formed simultaneously with formation of the substrate layer 12, or after the substrate layer 12 is formed, the minus electrode terminal can be separately derived from the thus formed substrate layer 12 by the use of a conductor.

On a surface of the substrate layer 12 formed as above, a collector electrode 14 made of aluminum and having a thickness of 0.4 μm was formed through an insulating layer. This collector electrode 14 is usually formed of an evaporated film of a bulb metal such as aluminum, stainless steel, chromium, tantalum, niobium or the like. Particularly in the present invention, the collector electrode is preferably formed of a metallic aluminum evaporated film. The thickness thereof is usually in the range of 0.1 to 0.3 μm. By forming a metallic aluminum layer having a thickness in such a range as above as the collector electrode 14, minus charge generated in an n-type compound semiconductor layer 16 to be laminated on the collector electrode 14 can be favorably accumulated on the substrate layer 14.

When the collector electrode 14 is formed by a deposition method using metallic aluminum, it is preferable to form the collector electrode 14 by depositing the metal under reduced pressure in an atmosphere of an inert gas such as nitrogen gas or argon gas while heating the metal to a temperature of not lower than the melting point of the metal.

On a surface of the thus formed collector electrode 14, an n-type compound semiconductor layer 18 can be directly formed, but adhesion of the n-type compound semiconductor 18 to the collector electrode 14 formed of the metallic aluminum evaporated layer is not always good, so that it is preferable to interpose a layer containing carbon (not shown in the drawing). The n-type compound semiconductor layer is preferably formed through at least one layer selected from the group consisting of a graphene layer, a graphite layer and a carbon nanotube layer, as the layer containing carbon. Here, the graphene layer is a single layer of carbon atom, and a graphite layer wherein at least a part of the graphene layer becomes a multilayer may be used, or a layer made of carbon nanotube that is a tube formed of carbon atoms may be used.

Particularly in the present invention, the layer containing carbon is preferably a graphene layer formed of a carbon single layer. Therefore, the mean thickness of the layer containing carbon is usually in the range of 0.01 to 10 nm. The graphene layer has only to be formed on at least a part of the surface of the collector electrode 14. Although the graphene layer is preferably formed all over the surface, the whole surface of the collector electrode 14 does not necessarily have to be coated with the graphene layer because the graphene layer is a carbon single layer.

In the present working example, a graphene layer having a mean thickness of 0.02 nm was formed.

In the photoelectric conversion element of the present invention, an n-type compound semiconductor layer 18 that is electrically connected to the collector electrode 14, on which such a graphene layer as above has been preferably formed, is formed.

The dielectric composition containing a fullerene, which forms the n-type compound semiconductor layer 18 and is used in the present invention, contains at least C₆₀ fullerene and/or C₇₀ fullerene, a conductive polymer and an organic pigment. Here, as fullerenes other than C₆₀ fullerene and C₇₀ fullerene, there can be mentioned C₆₂, C₆₈, C₈₀, C₈₂ and carbon nanotube (CNT). Further, small gap fullerene (SGF) is also included in C₆₀ fullerene.

In such an n-type compound semiconductor layer 16, it is preferable that regarding at least a part of the fullerene, electron transfer in the n-type compound semiconductor layer is made possible.

In the photoelectric conversion element of the present invention, at least a part of the fullerene that forms the n-type compound semiconductor layer is contained in the n-type compound semiconductor layer in such a manner that it is capable of molecular rotation.

Examples of the fullerenes for forming the n-type compound semiconductor layer include C₆₀, C₇₀, C₆₂, C₆₈, C₈₀, C₈₂ and carbon nanotube (CNT), and typical examples of the fullerenes that can be used in the present invention are shown below.

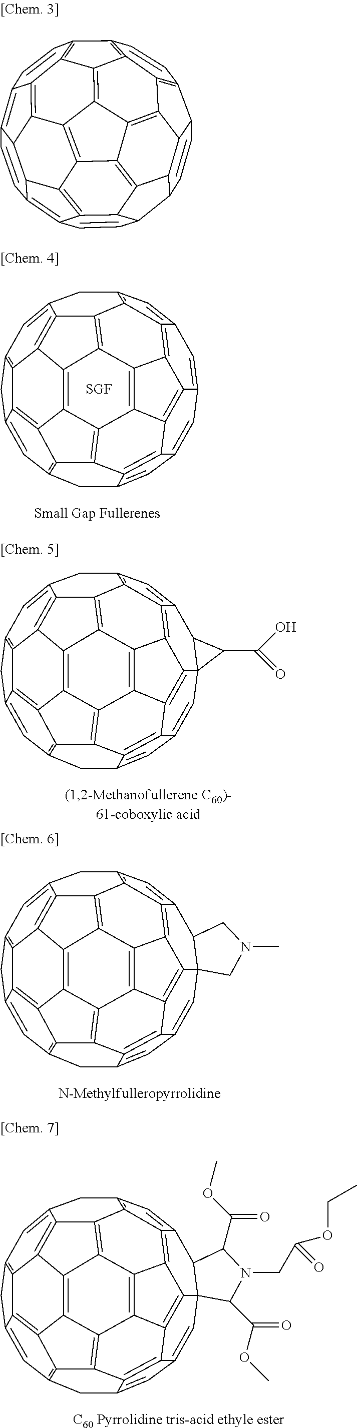

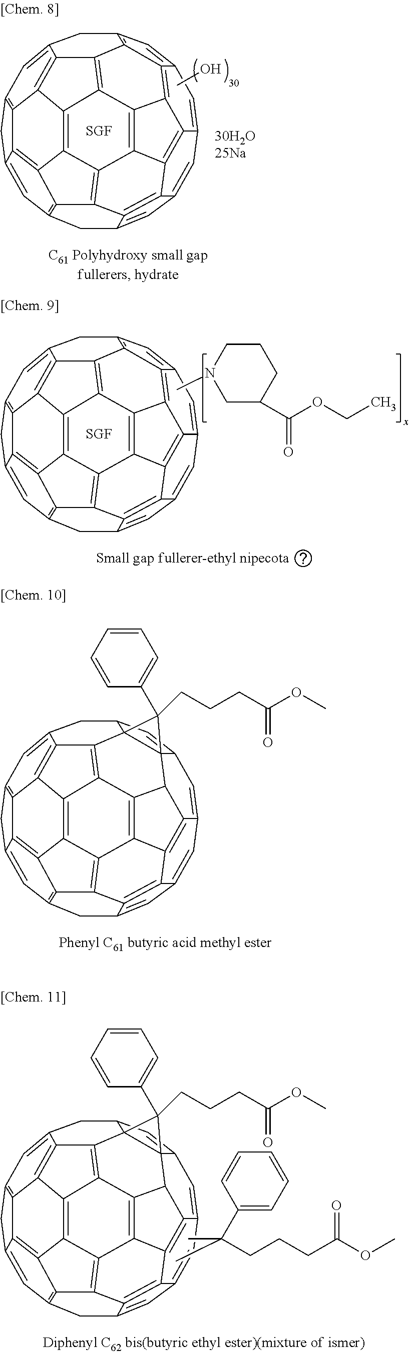

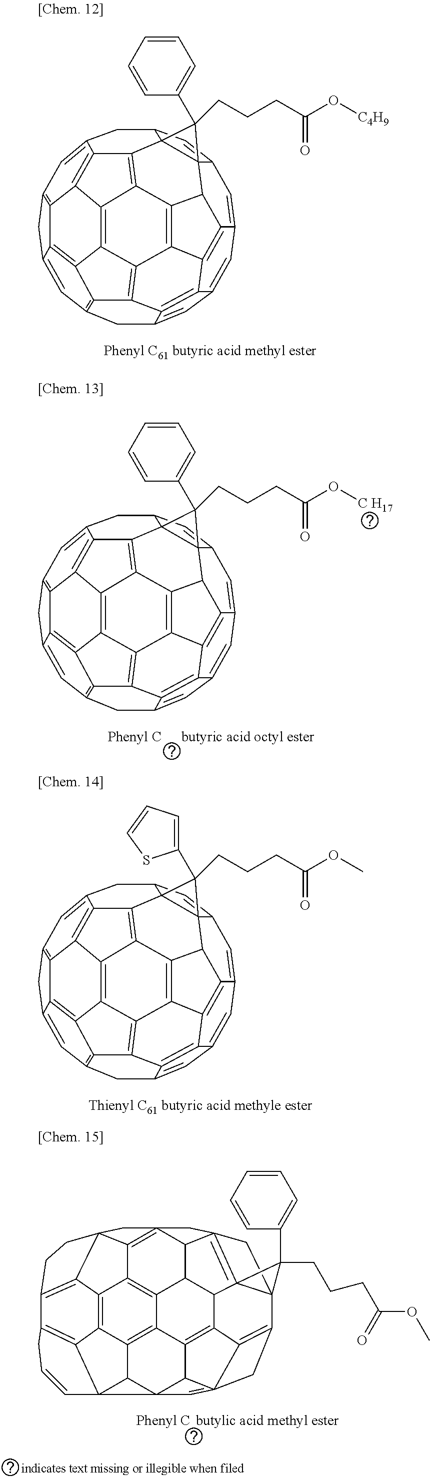

Particularly in the present invention, C₆₀ fullerene, C₇₀ fullerene and modified products thereof can be used singly or in combination.

Such fullerenes as above may be doped or intercalated with other elements. Examples of such elements include K and Ba. The elements for doping or intercalation are not limited to the above elements.

As described above, the fullerene may be an including fullerene that includes a metal atom in its hollow skeleton. Examples of such fullerenes include fullerene including potassium, fullerene including scandium, fullerene including lanthanum, fullerene including cesium, fullerene including titanium, fullerene including cesium/carbon, fullerene including cesium/nitrogen, C₈₀ fullerene including uranium, and C₈₂ fullerene including two uranium atoms. The including fullerenes are not limited to the above fullerenes.

In the dielectric composition for forming the n-type compound semiconductor layer 16 in the present invention, a conductive polymer is contained in addition to the above fullerene.

In the present working example, polyaniline or polythiophene is compounded as the conductive polymer.

Examples of the conductive polymers other than polyaniline and polythiophene, which can be used herein, include polyacetylene, poly(p-phenylenevinyl), polypyrrole, poly(p-phenyl sulfide), 5,5-dihexyl-2,2′-bithiophene (DH-2T), 2,2′,5,2″-trithiophene, α-quaterthiophene (4T), 3,3′″-dihexyl-2,2′,5′,2,5″,2′″-quaterthiophene (DH-4T), 3,3′″-didodecyl-2,2′:2″:5′,2″:5″,2′″-quaterthiophene, α-sexithiophene (6T), α,ω-dihexylsexithiophene (DH-6T), 5,5′-di(4-biphenylylyl)-2,2′-bithiophene, 5,5′-bis(2-hexyl-9H-fluoren-7-yl)-2,2′-bithiophene (DHFTTF), poly(3-hexylthiophene-2,5-diyl) (P3HT), poly(3-octylthiophen-2,5-yl (P3OT), poly(3-dodecylthiophen-2,5-yl) (P3DDT), poly[2-methoxy-5-(3′,7′-dimethyloctyloxy)-1,4-phenylenevinylene] (MDMP-PPV), poly[methoxy-5-(2-ethylhexyloxy)]-1,4-phenylenevinylene (MEH-PPV), poly[bis(4-phenyl)](2,4,6-trimethylphenylamine (PTAA), poly[9,9-dioctylfluorenyl-2,7-diyl]-co-bithiophene (F8T2) and poly(3-octylthiophene-2,5-diyl-co-desiloxythiophene-2,5-diyl) (POT-co-DOT). In the present invention, the conductive polymers are not limited to these polymers. In the present invention, these can be used singly or in combination. Particularly in the present invention, it is preferable to use α,ω-dihexylsexithiophene (DH-6T) and polyaniline singly or in combination.

In the dielectric composition for forming the n-type compound semiconductor layer 16 in the present invention, an organic pigment is compounded.

The organic pigment used herein may be an organic pigment itself or may be a precursor of an organic pigment. As a latent pigment used herein, there can be mentioned a precursor described in U.S. Pat. No. 6,071,989 (patent literature 4). Specifically, a compound represented by the following formula (1) can be mentioned.

A(B)ₓ (1)

In the formula (1), x represents an integer of 1 to 8, and when x is 2 to 8, each B may be the same or different.

In the formula (1), A represents a radical having anthraquinone-based, azo-based, benzimidazolone-based, quinacridone-based, quinophthalone-based, diketopyrrolopyrrole-based, dioxazine-based, indanthrone-based, indigo-based, isoindoline-based, isoindolinone-based, perylene-based or phthalocyanine based chromophore. A in the formula (1) is bonded to B through a hetero atom of A, such as N, O or S.

In the formula (1), B represents a radical selected from the group consisting of the following formulas (2), (3), (4), (5a) and (5b).

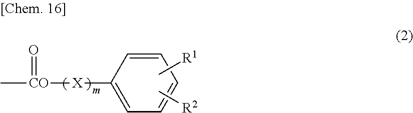

In the formula (2), m represents 0 or 1. X represents an alkenyl group of 2 to 5 carbon atoms, which is unsubstituted or may be substituted by an alkyl group of 1 to 6 carbon atoms or R⁵ or R⁶, or an alkylene group of 1 to 6 carbon atoms. Here, R⁵ and R⁶ each independently represent a hydrogen atom, an alkyl group of 1 to 24 carbon atoms, an alkyl group of 1 to 24 carbon atoms in which O is inserted, S is inserted, or an alkyl group of 1 to 6 carbon atoms di-substitutes and N is inserted, an alkenyl group of 3 to 24 carbon atoms, an alkynyl group of 3 to 24 carbon atoms, a halogen group, or a phenyl or biphenyl group substituted by a cyano group or a nitro group. In the present invention, the expression “a group such as O, S or N is inserted in an alkyl group” means that the alkyl group contains such a group in the middle of its carbon chain.

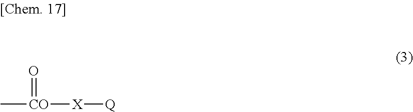

In the formula (3), X represents an alkenyl group of 2 to 5 carbon atoms, which is substituted or may be substituted by an alkyl group of 1 to 6 carbon atoms or R⁵ or R⁶, or an alkylene group of 1 to 6 carbon atoms, and Q represents a hydrogen atom, an alkyl group of 1 to 6 carbon atoms, CN group, CCl₃ group, a group shown below, SO₂CH₃ or SCH₃. R⁵ and R⁶ have the same meanings as those in the formula (2).

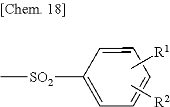

In the above formula, R¹ and R² have the same meanings as those in the formula (2).

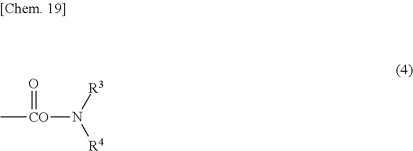

In the above formula (4), R³ and R⁴ are each independently a halogen group, an alkyl group of 1 to 4 carbon atoms or a group represented by the following formula. In the formula (4), R³ and R⁴ may be bonded to each other to form a piperidinyl group.

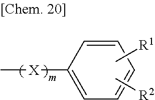

In the above formula, m, X, R¹ and R² have the same meanings as those in the formula (2).

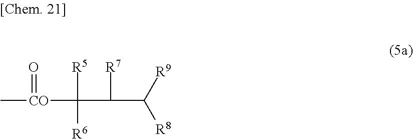

In the formula (5a), R⁵ and R⁶ each independently represent a hydrogen atom, an alkyl group of 1 to 24 carbon atoms, an alkyl group of 1 to 24 carbon atoms in which O is inserted, S is inserted, or an alkyl group of 1 to 6 carbon atoms di-substitutes and N is inserted, an alkenyl group of 3 to 24 carbon atoms, an alkynyl group of 3 to 24 carbon atoms, a halogen group, or a phenyl or biphenyl group substituted by a cyano group or a nitro group.

In the formula (5a), further, R⁷, R⁸ and R⁹ each independently represent a hydrogen atom, an alkyl group of 1 to 24 carbon atoms or an alkenyl group of 3 to 24 carbon atoms.

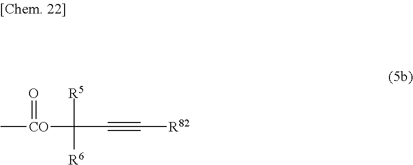

In the formula (5b), R⁵ and R⁶ each independently represent a hydrogen atom, an alkyl group of 1 to 24 carbon atoms, an alkyl group of 1 to 24 carbon atoms in which O is inserted, S is inserted, or an alkyl group of 1 to 6 carbon atoms di-substitutes and N is inserted, an alkenyl group of 3 to 24 carbon atoms, an alkynyl group of 3 to 24 carbon atoms, a halogen group, or a phenyl or biphenyl group substituted by a cyano group or a nitro group. In the formula (5b), further, R⁸² represents an alkyl group or any one of the following groups.

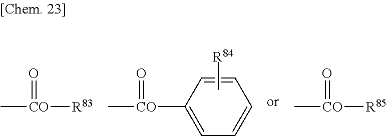

In the above formulas, R⁸³ represents an alkyl group of 1 to 6 carbon atoms, R⁸⁴ represents a hydrogen atom or an alkyl group of 1 to 6 carbon atoms, and R⁸⁵ represents an alkyl group, or a phenyl group which is unsubstituted or substituted by an alkyl group of 1 to 6 carbon atoms.

In the aforesaid formula (1), B represents a group represented by the following formula.

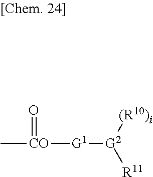

Here, G¹ represents a p,q-alkylene group of 2 to 12 carbon atoms, which is unsubstituted or substituted by a saturated hydrocarbon group of 1 to 12 carbon atoms, an alkoxy group of 1 to 12 carbon atoms, an alkylthio group of 1 to 12 carbon atoms or a dialkylamino group of 2 to 24 carbon atoms. Here, p and q represent position numbers different from each other, and the alkylene group may be substituted by one substituent or may be substituted by two or more substituents.

G² represents any one hetero atom selected from the group consisting of N, O and S. When G² is O or S, i is 0. When G² is N, i is 1.

R¹⁰ and R¹¹ each independently represent [(p′,q′-alkyl group of 2 to 12 carbon atoms)-R¹²]ᵢᵢ-(alkyl group of 1 to 12 carbon atoms) {namely, a group wherein ii repeating structures, in each of which P′,q′-alkyl group of 2 to 12 carbon atoms and R¹² are bonded to each other, are bonded, and alkyl group of 1 to 12 carbon atoms is bonded at the end on the R¹² side}, or an unsubstituted or substituted alkyl group of 1 to 12 carbon atoms.

Examples of the substituents of the alkyl group of 1 to 12 carbon atoms include an alkoxy group of 1 to 12 carbon atoms, an allylthio group of 1 to 12 carbon atoms, a dialkylamino group of 2 to 24 carbon atoms, an allylthio group of 6 to 12 carbon atoms, an alkylallylamino group of 7 to 24 carbon atoms and a diallylamino group of 12 to 24 carbon atoms. The alkyl group may be substituted by one substituent or may be substituted by two or more substituents.

The above ii represents a number of 1 to 1000, and p′ and q′ represent position numbers different from each other. Each R¹² independently represents O, S, or N substituted by an alkyl group or represents an alkylene group of 2 to 12 carbon atoms. The repeating structure has the same meaning as previously described.

R¹⁰ and R¹¹ may be each saturated or may each have 1 to 10 unsaturated bonds. In each of R¹⁰ and R¹¹, a group such as —(C═O) or —C₆H₄— may be introduced at an arbitrary position. Further, R¹⁰ and R¹¹ may be each unsubstituted or may each have 1 to 10 substituents such as halogen atoms, cyano groups and nitro groups.

However, when -G¹- is —(CH₂)ᵢᵥ—, iv represents an integer of 2 to 12, G² represents S, and R¹¹ is not an unsubstituted or substituted alkyl group of 1 to 4 carbon atoms in which not carbon but O, S or N is inserted in the middle of the carbon chain.

Another example of the latent pigment for use in the present invention is a compound represented by the following formula (6).

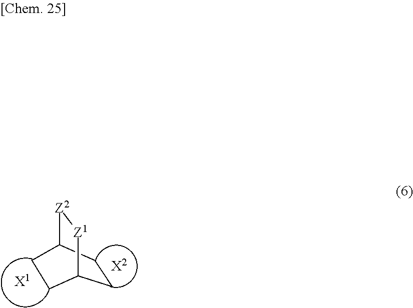

In the formula (6), at least one of X¹ and X² represents a group which forms a π-conjugated divalent aromatic ring, and Z¹-Z² represents a group which is capable of elimination by heat or light so that a π-conjugated compound obtained by elimination of Z¹-Z² may become a pigment molecule, and of X¹ and X², a group which does not form a π-conjugated divalent aromatic ring represents a substituted or unsubstituted ethenylene group.

From the compound represented by the formula (6), Z¹-Z² is eliminated by heat or light to produce a π-conjugated compound having high planarity, as shown by the following chemical reaction. In the present invention, this π-conjugated compound produced becomes an organic pigment to be compounded in the n-type compound semiconductor layer. This organic pigment is a semiconductor.

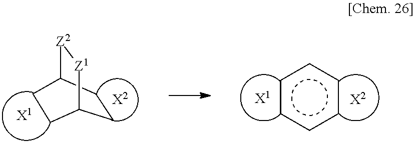

Examples of the compounds represented by the formula (6) include the following compounds.

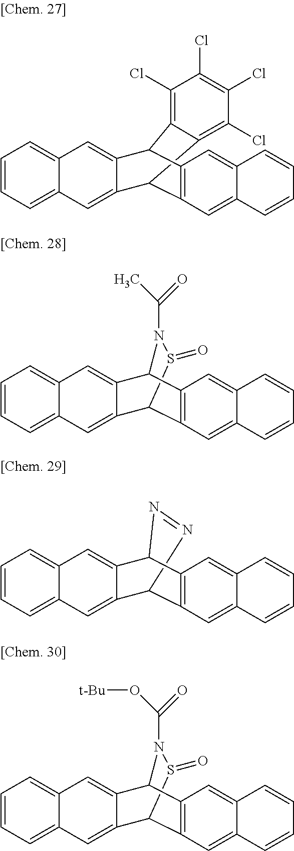 [SMILES: Clc1c(Cl)c(Cl)c2c(c1Cl)C1c3cc4ccccc4cc3C2c2cc3ccccc3cc21 ; CC(=O)N1C2c3cc4ccccc4cc3C(c3cc4ccccc4cc32)S1=O ; c1ccc2cc3c(cc2c1)C1N=NC3c2cc3ccccc3cc21 ; CC(C)(C)OC(=O)N1C2c3cc4ccccc4cc3C(c3cc4ccccc4cc32)S1=O]

By applying light or heat to the above compounds, compounds which have high planarity as shown by, for example, the following formula and are π-conjugated can be obtained from the above latent organic pigments.

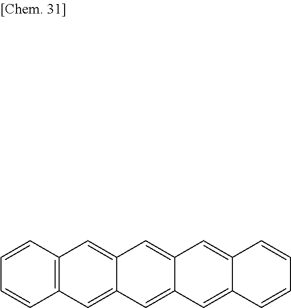 [SMILES: c1ccc2cc3cc4cc5ccccc5cc4cc3cc2c1]

The organic pigment has low dispersibility in a solvent similarly to a fullerene, and it is difficult to produce a dielectric composition of high homogeneity, which contains a fullerene, a conductive polymer and an organic pigment and forms the n-type compound dielectric layer 16 in the present invention. However, by dispersing such a precursor as above in a dispersion medium to form a homogeneous composition and then heating the composition, an organic pigment is produced from the precursor, whereby a dielectric composition having high homogeneity can be obtained.

In the present working example, phthalocyanine (H₂Pc) was compounded as the organic pigment.

Examples of the organic pigments other than phthalocyanine, which are to be contained in the dielectric composition for forming the n-type compound semiconductor layer, include metal complexes of phthalocyanine; tetrabenzoporphyrin and its metal complexes; tetracene (naphthacene); polyacenes, such as pentacene, pyrene and perylene; perfluoro compounds of organic pigments, e.g., oligothiophenes such as sexithiophene; and aromatic carboxylic anhydrides and imidization products thereof, such as naphthalenetetracarboxylic anhydride, napthalenetetracarboxylic acid diimide, perylenetetracarboxylic anhydride and perylenetetracarboxylic acid diimide, and derivatives having these compounds as skeletons. These can be used singly or in combination. Examples of the precursors of the organic pigments for forming the n-type compound dielectric layer are shown below.

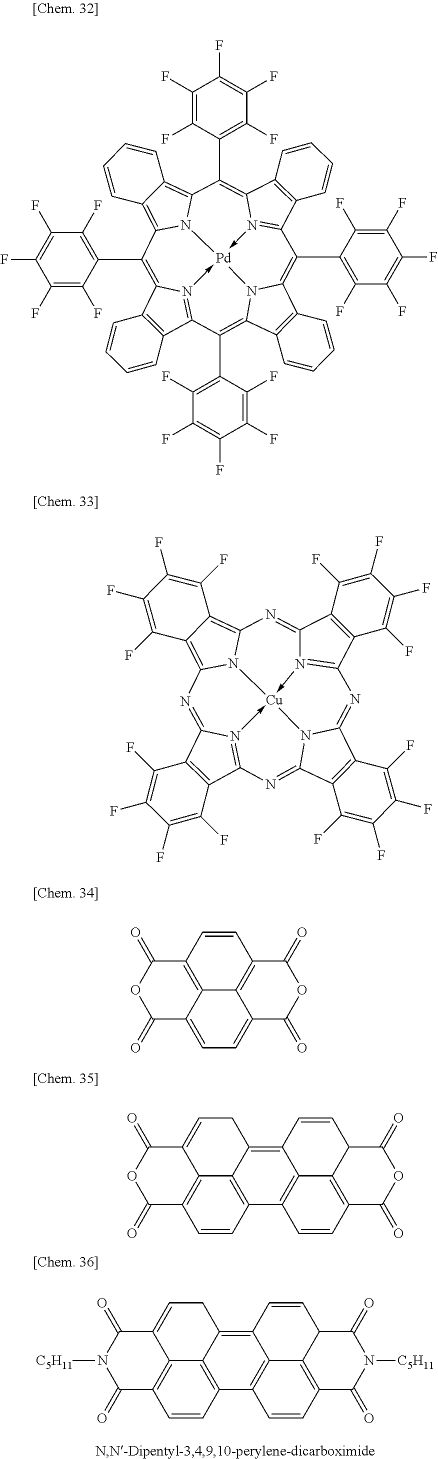

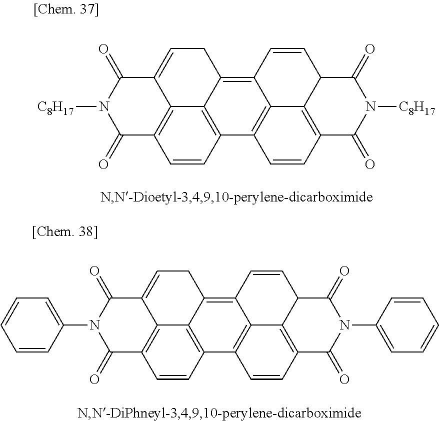

Such an organic pigment precursor as above is converted into an organic pigment by dissolving or dispersing it in a polar solvent such as N-methyl-2-pyrrolidone (NMP) or chloroform and heating the solution or the dispersion usually at a temperature of not lower than 100° C., preferably at a temperature of not lower than 150° C., usually for not shorter than 30 seconds, preferably for not shorter than 1 minute. In the thermal conversion into the organic pigment, the upper limit of the heating temperature and the upper limit of the heating time are not specifically restricted, but thermal decomposition of the organic pigment begins at, for example, a temperature of about 400° C., and even if the organic pigment precursor is heated for longer than 100 hours, an effect due to the prolonged heating time is not obtained.

An example of the reaction to form the organic dye from the organic dye precursor by heating is shown below.

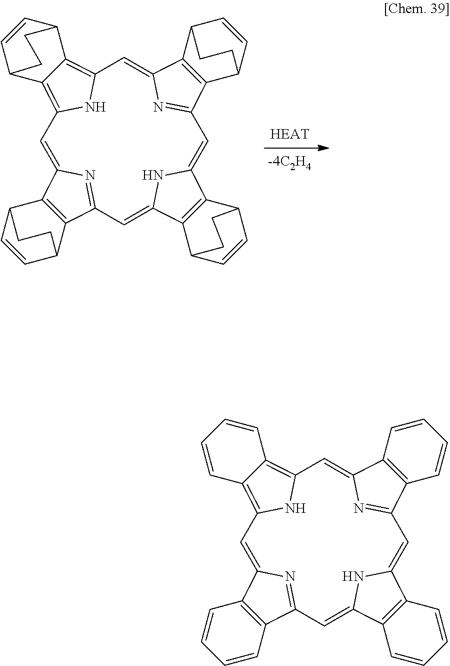 [SMILES: C1=CC2CCC1C1=C2c2cc3[nH]c(cc4nc(cc5[nH]c(cc1n2)c1c5C2C=CC1CC2)C1=C4C2C=CC1CC2)c1c3C2C=CC1CC2 ; c1ccc2c(c1)-c1cc3[nH]c(cc4nc(cc5[nH]c(cc-2n1)c1ccccc51)-c1ccccc1-4)c1ccccc31]

The above thermal conversion is carried out usually in an atmosphere of an inert gas such as nitrogen gas or argon gas.

The compounding ratio between the fullerene, the conductive polymer and the organic pigment in the dielectric composition used in the present invention is 1:1:1 by weight (fullerene:conductive polymer:organic pigment) based on the total of those three components.

In the present invention, the n-type semiconductor layer can be also formed from C₆₀ fullerene, graphene, phthalocyanine (H₂Pc), molybdenum oxide, etc. which are n-type nanocarbon materials. An SEM photograph (40000 magnifications) of the n-type nanocarbon materials of such components as above is shown in FIG. 9.

The dielectric composition of such constitution was laminated on the collector electrode 14, preferably on the graphene layer formed on the surface of the collector electrode 14, by deposition or casting to form the n-type compound semiconductor layer 16 having a thickness of 2 μm.

The thickness of the n-type compound semiconductor layer 16 can be usually set to 1 to 10 μm, preferably 1 to 2 μm.

The method for forming the n-type compound semiconductor layer 16 is not specifically restricted. Although the dielectric composition may be dissolved or dispersed in a solvent and applied by a publicly known method such as spin coating, the n-type compound semiconductor layer can be formed by depositing the dielectric composition. In this case, CVD, vacuum deposition, sputtering or the like can be adopted, and it is preferable to form the n-type compound semiconductor layer by vacuum deposition or casting under the conditions of an inert gas.

In the present working example, after the n-type compound semiconductor layer 16 is formed as above, a p-type compound semiconductor layer 18 can be formed in such a manner that this layer comes into contact with the surface of the n-type compound semiconductor layer 16. However, it is preferable that a pn-bulk layer 20 is intermittently formed on the surface of the n-type compound semiconductor layer 16, and thereafter, the p-type compound semiconductor layer 18 is formed. This pn-bulk layer is a layer which is formed of a ferroelectric substance and in which electrons that are carriers and positive holes that are carriers are balanced. This pn-bulk layer 20 is intermittently in contact with both of the p-type compound semiconductor layer 18 and the n-type compound semiconductor layer 18.

On a surface of the n-type compound semiconductor layer 16 formed as above, the pn-bulk layer is formed.

That is to say, after the n-type compound semiconductor layer 16 is formed as above, the p-type compound semiconductor layer 18 may be formed in such a manner that this layer comes into contact with the surface of the n-type compound semiconductor layer 16, but on the surface of the n-type semiconductor layer 16, the pn-bulk layer 20 (i layer) is intermittently formed, and on the surface of this pn-bulk layer 20, the p-type compound semiconductor layer 18 is laminated.

This pn-bulk layer is a layer which is formed of a ferroelectric substance and in which electrons that are carriers and positive holes that are carriers are balanced. This pn-bulk layer 20 is intermittently in contact with both of the p-type compound semiconductor layer 18 and the n-type compound semiconductor layer 18.

The pn-bulk layer 20 can be formed by intermittently depositing a ferroelectric, such as lead titanate, lead(II) zirconate titanate or strontium titanate, on the surface of the n-type semiconductor layer 18.

In the present working example, the pn-bulk layer was deposited in a mean thickness of 2.0 μm. However, the mean thickness of the pn-bulk layer is usually 1 to 2 μm, and this layer is intermittently formed on the surface of the n-type compound semiconductor layer 16, so that this layer is intermittently in contact with not only the n-type compound semiconductor layer 16 but also the p-type compound semiconductor layer 20. The n-type compound semiconductor layer 18 is also in contact with the p-type compound semiconductor layer 20 through gaps of the pn-bulk layer.

By forming the pn-bulk layer 20 as above, the fullerene contained in the n-type compound semiconductor layer 16 is always in contact with the pn-bulk layer 20. In the n-type compound semiconductor layer 16, the fullerene is rotating at a high speed, and this rotation vibration of the fullerene acts on the ferroelectric component of the pn-bulk layer 20, and by virtue of the piezoelectric effect, electromotive force is generated also in the pn-bulk layer 20. In the present working example, the electromotive force generated by the piezoelectric effect is also used.

In the present working example, the pn-bulk layer 20 is formed as above, and the p-type compound semiconductor layer 18 is formed in such a manner that this layer comes into contact with the pn-bulk layer.

The p-type compound semiconductor layer 18 is preferably a transparent evaporated film formed from an oxide comprising silicon dioxide containing a dopant that forms a positive hole. As the dopant that forms a positive hole, phosphorus, boron or the like can be mentioned. If silicon dioxide is doped with such a dopant, a positive hole is formed in the p-type compound semiconductor layer 18 formed of silicon dioxide, and the positive hole thus formed looks as if it could freely transfer in the p-type compound semiconductor layer 18.

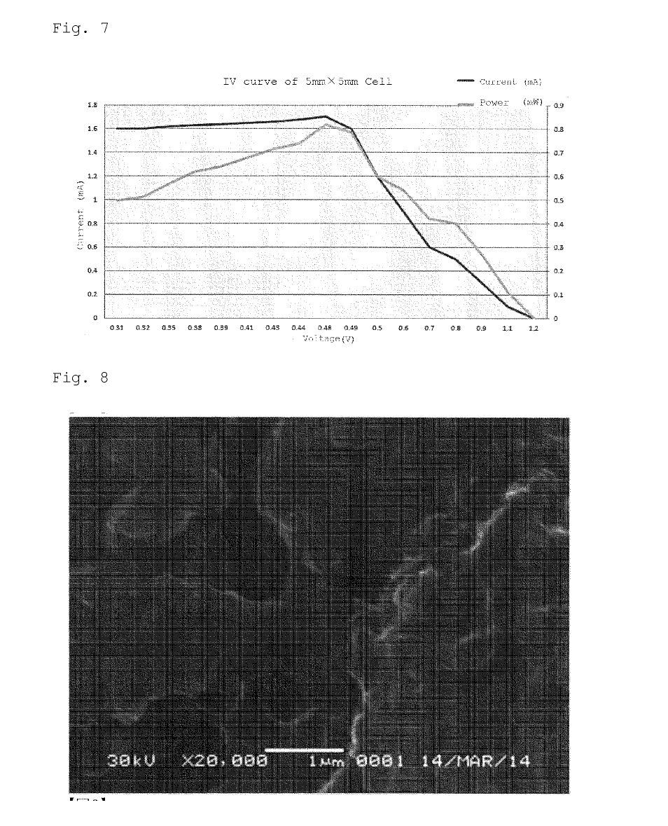

The p-type compound semiconductor layer 18 can be also preferably formed from polyaniline and graphene. An example of an SEM photograph of the p-type compound semiconductor layer formed from polyaniline and graphene is shown in FIG. 8. The magnifications of the SEM photograph are 20000.

In the present working example, the p-type compound semiconductor layer 18 was formed by vacuum deposition or casting so as to have a thickness of 2.0 μm.

The p-type compound semiconductor layer 18 may contain boron as a dopant.

It is advantageous to form such a p-type compound semiconductor layer 18 by deposition. When the p-type compound semiconductor layer is formed by a deposition method, the layer can be formed by using silicon dioxide containing the dopant and by adopting CVD, vacuum deposition, sputtering or the like, and it is preferable to carry out vacuum deposition under the conditions of an inert gas.

The p-type compound semiconductor layer 18 can be also formed by a casting method.

On the p-type compound semiconductor layer 18 formed as above, a pump 66 is formed at the position corresponding to the bump 68 formed on the plus electrode 11, and the bump 66 and the bump 68 are connected to each other using a copper wire (conductor wire 69).

In the present invention, it is enough just to laminate the above layers in this order, but the order of formation may be reversed.

According to the photoelectric conversion element formed as above, a positive hole transfers to the plus electrode 11 through the conductor wire 69, and a potential difference is produced between the plus electrode terminal 64 of the plus electrode 11 and the minus electrode terminal 62 derived from the substrate layer 12.

The n-type compound semiconductor layer 16 formed from the dielectric composition prepared as above contains at least a fullerene, a conductive polymer and an organic dye, and when such an n-type compound semiconductor layer 16 is irradiated with light, the light is absorbed by the organic pigment to bring about charge separation in the conductive polymer, as shown by, for example, the following formula, and an electron excited and released reaches the fullerene and then reaches the substrate layer through the collector electrode 14 to negatively charge the substrate layer 16.

When the plus electrode terminal 64 is connected to the minus electrode terminal 62 through a resistance, a positive hole generated in the p-type compound semiconductor layer 18 and an electron generated in the n-type compound semiconductor layer 16 flow in the circuit to bring about positive charge transfer and charge recombination in the n-type compound semiconductor layer, as shown below, whereby the excited organic pigment is returned to its original state.

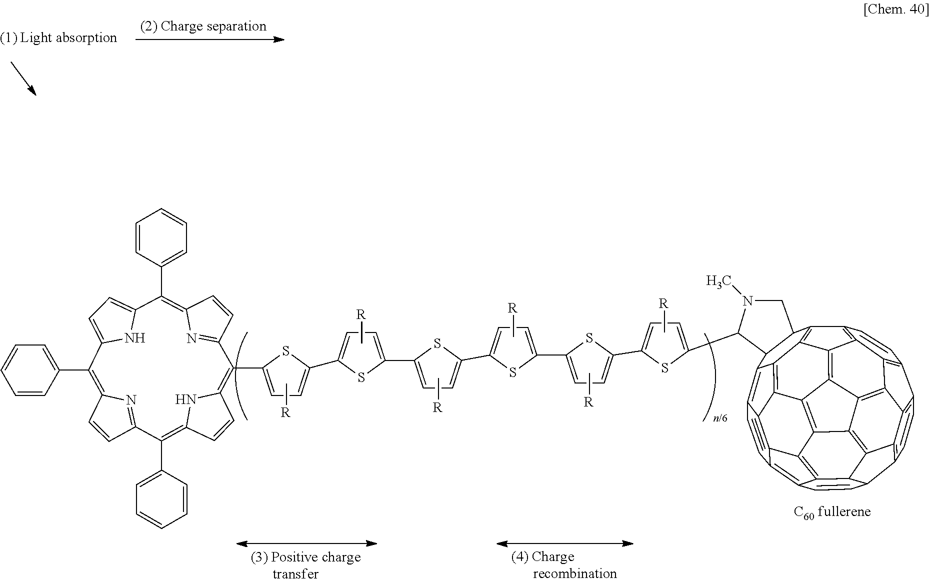

In the present working example, n in the above formula is 300, and R represents a hydrocarbon group. The part of the organic pigment in the above formula is the aforesaid organic pigment such as phthalocyanine or a precursor of the organic pigment.

Current flows as above, and as a result, a difference in temperature occurs between the front surface and the back surface of a cell of the photoelectric conversion element of the present invention. This difference in temperature allows the photoelectric conversion element to generate electromotive force by virtue of Seebeck effect, and in the present invention, therefore, electromotive force attributable to the Seebeck effect can be also utilized.

Although the photoelectric conversion element of the present invention has such constitution as above, it has a surface protective layer 24 on the surface of the p-type compound semiconductor layer. This surface protective layer 24 is formed of a polymer film or sheet, and when the photoelectric conversion element of the present invention is used as a flexible photoelectric conversion element, the thickness of this surface protective layer 24 is usually not more than 200 μm. The thickness of the surface protective layer can be set usually in the range of 50 to 3000 μm. By virtue of the surface protective layer 24, the surface of the p-type compound semiconductor layer 18 is protected, and besides, the photoelectric conversion element of the present invention can be handled as a flexible film. By compounding infrared conversion particles in the surface protective layer 24 within limits not detrimental to the transparency of the surface protective layer, not only visible rays but also rays that are not attributable to sunlight, such as infrared rays and far infrared rays, can be absorbed. Therefore, power generation not attributable to visible light becomes feasible.

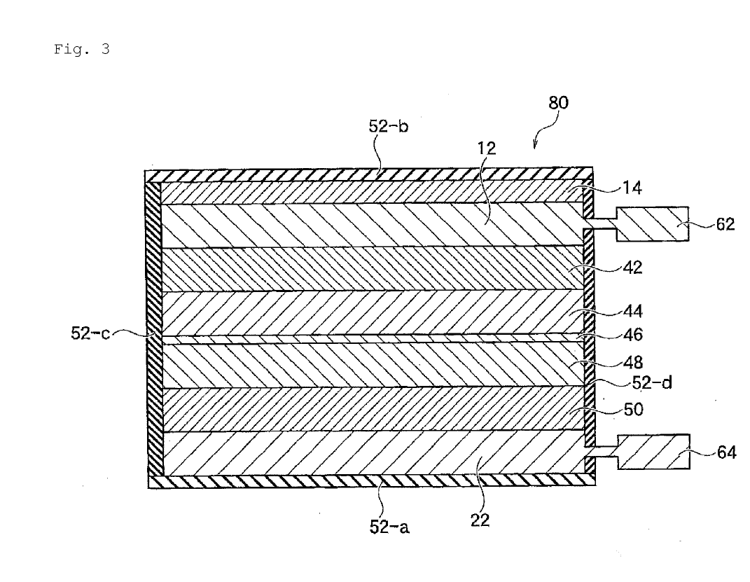

In FIG. 4, an example of a light absorption band of a photoelectric conversion element obtained when (far) infrared-emitting inorganic powder is compounded in the surface protective layer as the infrared conversion particles is shown.

As a matter of course, the photoelectric conversion element of the present invention can absorb visible light to generate power as described above, and it can absorb also light of infrared region of a wavelength of 7 μm to 14 μm to effectively generate power, as shown in FIG. 4.

A secondary battery, which is laminated on the photoelectric conversion element having such constitution as above to form a photoelectric conversion element having a storage/discharge function, usually has such constitution as shown below.

[Secondary Battery]

In the photoelectric conversion element 80 having storage/discharge ability, a secondary battery minus electrode face 42 is laminated on a surface of a substrate layer 12 where a collector electrode 14 is not provided, as shown in FIG. 3. The collector electrode is usually formed of an evaporated film of a bulb metal such as aluminum, stainless steel, chromium, tantalum, niobium or the like.

In this secondary battery, the secondary battery minus electrode face 42 can be formed from an oxide comprising silicon dioxide. Here, the main component of the oxide to form the secondary battery minus electrode face is silicon dioxide, and the silicon dioxide is usually doped with a dopant. The dopant used herein facilitates accumulation of minus charge on the secondary battery minus electrode face 42 described later, and examples of such dopants include Br and I. Such a dopant is used usually in an amount of 0.01 to 1 part by weight based on 100 parts by weight of silicon dioxide. By using the dopant in such an amount as above, minus charge can be efficiently transferred.

Such a secondary battery minus electrode face 42 can be usually formed by depositing silicon dioxide containing a dopant, when needed. For the deposition, CVD, vacuum deposition, sputtering or the like can be adopted, but in particular, it is preferable to carry out vacuum deposition in an inert gas. The deposition temperature is usually 350 to 500° C., preferably 350 to 450° C., and as the inert gas, nitrogen gas, argon gas or the like can be used.

The thickness of the secondary battery minus electrode face 42 formed as above is usually 0.1 to 100 μm.

On a surface of the secondary battery minus electrode face 42 provided when needed, a ferroelectric layer (first electrolyte layer) 44 is laminated. In the ferroelectric layer 44 in the photoelectric conversion element 70 having storage/discharge ability, a water-soluble electrolytic solution is not used. In the photoelectric conversion element 70 having storage/discharge ability of the present invention, a nonaqueous electrolyte containing an ionic liquid electrolyte can be used as the electrolyte. Such nonaqueous electrolytes can be used singly or in combination. By using such a nonaqueous electrolyte, corrosion of the secondary battery can be effectively prevented.

Examples of the ionic liquids that are nonaqueous electrolytes include the following salts each consisting of a cation and an anion.

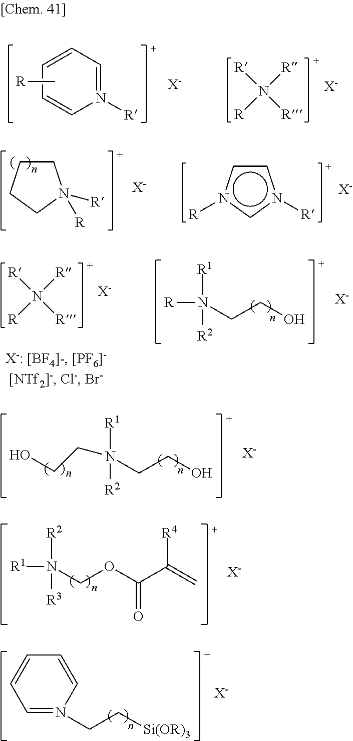

For the nonaqueous electrolyte for forming the ferroelectric layer 44 of the secondary battery 80, ammonium-based ions, such as imidazolium salt and pyridinium salt, or phosphonium-based ions are preferably used, and as the anions, halogen-based ions, such as bromide ion and triflate, boron-based ions, such as tetraphenyl borate, and phosphorus-based ions, such as hexafluorophosphate ion, are preferably used in proper combination.

In the ferroelectric layer 44 of the secondary battery, a cationic polymer electrolyte and/or an anion molecule electrolyte may be contained in addition to the above ionic liquid.

Examples of the anionic polymer electrolytes that are anionic electrolytes and the cationic polymer compounds that are cationic electrolytes include polymer compounds, such as perfluorosulfonic acid polymer, poly(allylbiguanido-co-allylamine) (PAB) and poly(allyl-N-carbamoylguanidino-co-allylamine) (PAC).

In the ferroelectric layer 44, at least one ferroelectric selected from the group consisting of lead titanate, lead(II) zirconate titanate and strontium titanate is contained as a ferroelectric.

In the ferroelectric layer 44 of the secondary battery 80, a general-purpose resin, such as polyolefin, polyester, polyether, polyamide, polyamidoimide or polyimide, may be compounded within limits not detrimental to the properties of the ferroelectric layer 44. The amount of such a general-purpose resin compounded is usually less than 50 parts by weight when the amount of the components for forming the ferroelectric layer 44 is 100 parts by weight.

The ferroelectric layer 44 in the secondary battery 80 contains a ferroelectric, and contains, if necessary, such an ionic liquid as above and an anionic electrolyte and/or a cationic electrolyte. The ferroelectric layer 44 can be formed by applying a solution or a dispersion, which contains, if necessary, the ionic liquid, the electrolyte, etc. in amounts not detrimental to the properties of the ferroelectric layer 44. The thickness of the ferroelectric layer 44 thus formed is usually in the range of 0.01 to 10 μm.

In the secondary battery 80, the ferroelectric layer 44 having such constitution as above is laminated on an ion supply substance layer 48 through a solid electrolyte layer 46.

In the secondary battery 80, the solid electrolyte layer 46 is a layer formed so that it may part the ferroelectric layer 44 from the ion supply substance layer 48 and electrons can transfer from the layer but the electrolyte cannot transfer from the layer, and for example, there can be used a reverse osmosis membrane (RO membrane), an ion exchange resin membrane, or a layer formed from a paste kneadate obtained by kneading an ion conductive substance of an amorphous structure containing a vanadate or the like as a main component with paraffin wax or the like as an adhesive. Such a solid electrolyte layer 46 may be formed by coating a surface of the ferroelectric layer 44 with a coating liquid obtained by dissolving or dispersing a resin having reverse osmosis property or an ion exchange resin in a solvent or the paste kneadate prepared as above using a publicly known method, or may be formed by laminating a membrane that has been separately formed in advance using the coating liquid.

The thickness of the solid electrolyte layer 46 thus formed is usually in the range of 0.01 to 100 μm, preferably 0.1 to 100 μm. By setting the thickness of the solid electrolyte layer 46 as above, the secondary battery 80 can be efficiently used, and besides, occurrence of short circuit can be effectively prevented.

On a surface of such a solid electrolyte layer 46 as above where the ferroelectric layer 44 is not provided, an ion supply substance layer 48 is laminated.

In the ion supply substance layer 48 in the secondary battery 80, a water-soluble electrolytic solution is not used. In such a photoelectric conversion element 70 having storage/discharge ability as above, a nonaqueous electrolyte containing an ionic liquid electrolyte can be used as the electrolyte. Such nonaqueous electrolytes can be used singly or in combination. By the use of such a nonaqueous electrolyte, corrosion of the secondary battery can be effectively prevented.

Examples of the ionic liquids that are nonaqueous electrolytes include the following salts each consisting of a cation and an anion.

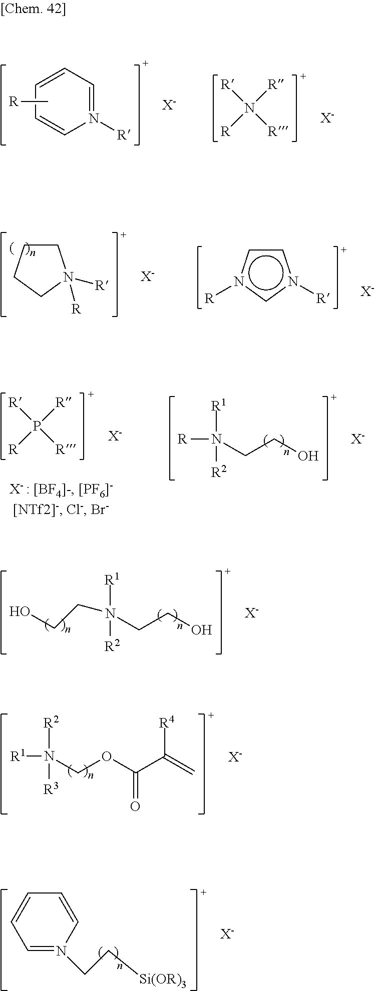

For the nonaqueous electrolyte for forming the ion supply substance layer 48 of the secondary battery 80, ammonium-based ions, such as imidazolium salt and pyridinium salt, or phosphonium-based ions are preferably used, and as the anions, halogen-based ions, such as bromide ion and triflate, boron-based ions, such as tetraphenyl borate, and phosphorus-based ions, such as hexafluorophosphate ion, are preferably used in proper combination.

In the ion supply substance layer 48 of the secondary battery 80, a cationic polymer electrolyte and/or an anion molecule electrolyte may be contained in addition to such an ionic liquid as above.

Examples of the anionic polymer electrolytes that are anionic electrolytes and the cationic polymer compounds that are cationic electrolytes include polymer compounds, such as perfluorosulfonic acid polymer, poly(allylbiguanido-co-allylamine) (PAB) and poly(allyl-N-carbamoylguanidino-co-allylamine) (PAC).

In the present invention, halides of alkali metals, such as KCl, NaCl and LiCl, can be also used for the ion supply substance layer 48. When such a halide of an alkali metal is used as the ion supply substance, the halide of an alkali metal, and graphene, graphite, carbon nanotube or the like are ground in a solid phase, then the resulting powder is dispersed in an organic solvent such as N-methyl-2-pyrrolidone (NMP) to prepare a casting liquid, the casting liquid is cast, then the organic solvent is removed to form a cast layer, and this cast layer can be used. When such a halide of an alkali metal as above is used, the potential of the storage layer usually varies as follows depending upon the alkali metal used.

Potassium (K): −2.925 V

Sodium (Na): −2.714 V

Lithium (Li): −3.045 V

In the ion supply substance layer 48 of the secondary battery 80, a general-purpose resin, such as polyolefin, polyester, polyether, polyamide, polyamidoimide or polyimide, may be compounded within limits not detrimental to the properties of the ion supply substance layer 48. The amount of such a general-purpose resin compounded is usually less than 50 parts by weight when the amount of the components for forming the ion supply substance layer 48 is 100 parts by weight.

The ion supply substance layer 48 in the secondary battery 80 contains an ion supply substance, and contains, if necessary, such an ionic liquid as above and an anionic electrolyte and/or a cationic electrolyte. The ion supply substance layer 48 can be formed by applying a solution or a dispersion, which contains, if necessary, the ionic liquid, the electrolyte, etc. in amounts not detrimental to the properties of the ion supply substance layer 48. The thickness of the ion supply substance layer thus formed is usually in the range of 0.01 to 10 μm.

The ferroelectric layer 44 has composition containing a ferroelectric as an essential component, while the ion supply substance layer 48 contains an ion supply substance as an essential component, and the compositions of these layers are usually different as described above, but they may be the same as each other.

On a surface of such an ion supply substance layer 48 as above where the solid electrolyte layer 46 is not laminated, a secondary battery plus electrode face 50 is formed.

At least one carbon material selected from the group consisting of fullerenes, graphene and carbon nanotube (CNT) is used herein.

As the fullerenes for use herein, the same fullerenes as the aforesaid ones can be used. Examples of such fullerenes include the following fullerenes.

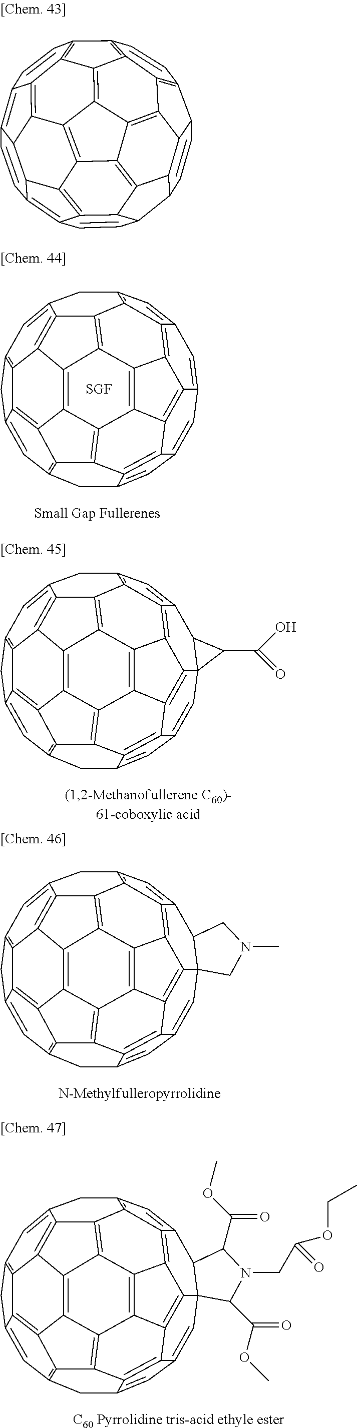

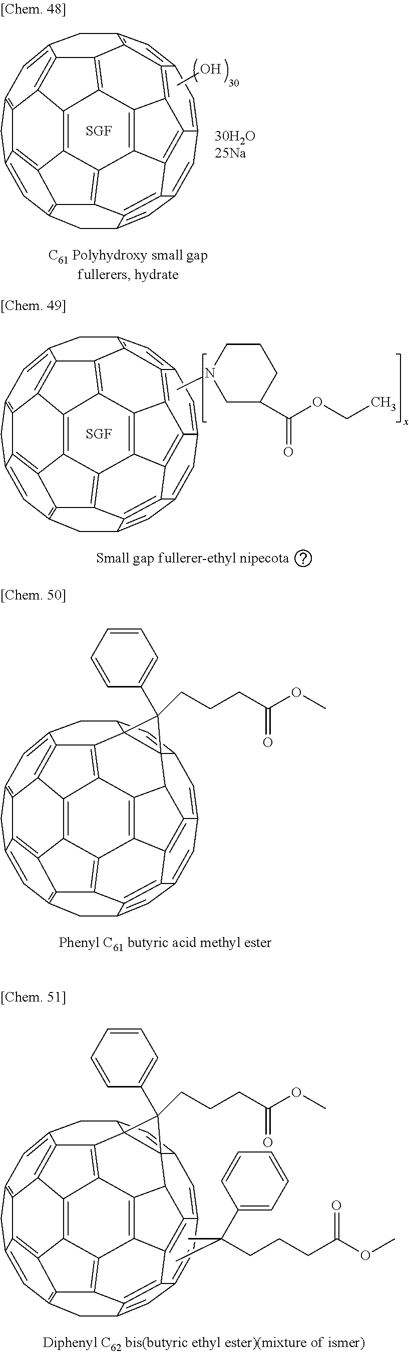

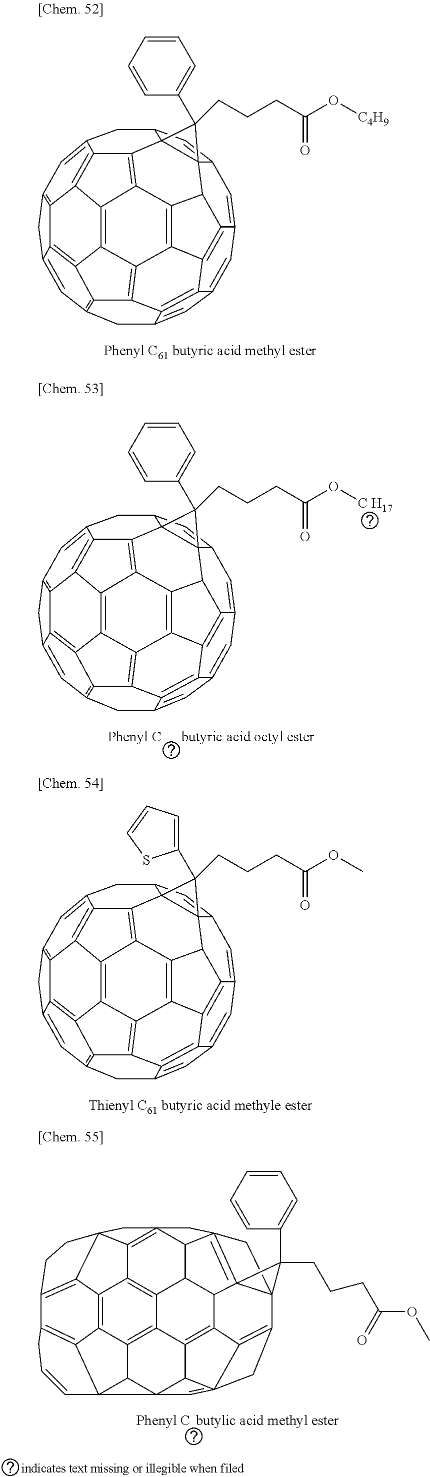

The graphene layer for forming the secondary battery plus electrode face 50 in the secondary battery 80 is a single layer of carbon atom, and it is difficult to form a homogeneous graphene layer, so that a graphite layer wherein at least a part of the graphene layer becomes a multilayer may be used. Further, a layer made of carbon nanotube (CNT) that is a tube formed of continuous carbon atoms may be used. Particularly in the present invention, the layer containing carbon is preferably a graphene layer formed of a carbon single layer. Therefore, the mean thickness of the layer containing carbon is usually in the range of 0.01 to 10 nm. The graphene layer has only to be formed on at least a part of the surface of the secondary plus electrode 50. Although the graphene layer is preferably formed all over the surface, the whole surface of the secondary battery electrolyte layer 48 does not necessarily have to be coated with the graphene layer because the graphene layer is a carbon single layer.

On a surface of the secondary battery plus electrode face 50 where the ferroelectric layer 48 is not formed, a secondary battery plus electrode 22 is formed.

The secondary battery plus electrode 22 is formed of a copper or pure copper powder deposit, and at one end of the secondary battery plus electrode 22, a plus electrode terminal 64 is formed.

The secondary battery of the present invention having such constitution is surrounded and sealed by insulators 52-a, 52-b, 52-c and 52-d. From the substrate layer 12 of the secondary battery, a minus electrode terminal 62 is derived, and from the plus electrode 22, a plus electrode terminal 64 is derived.

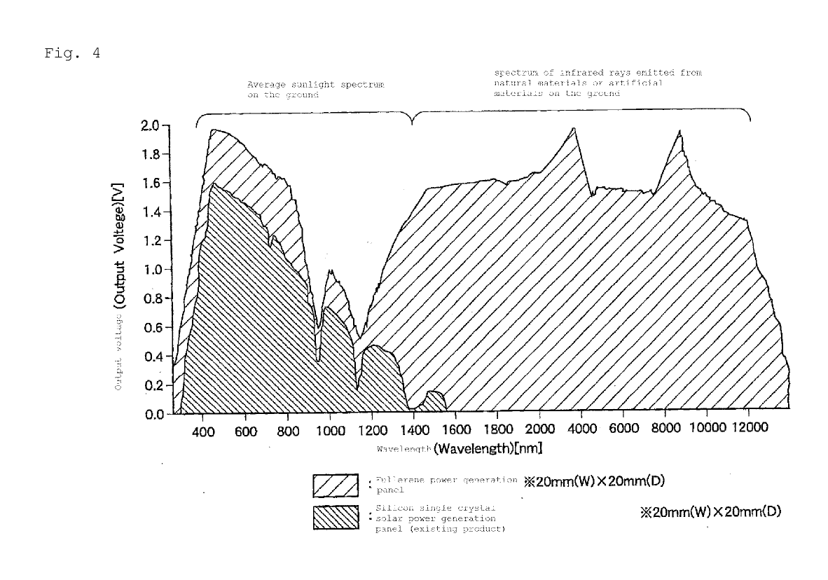

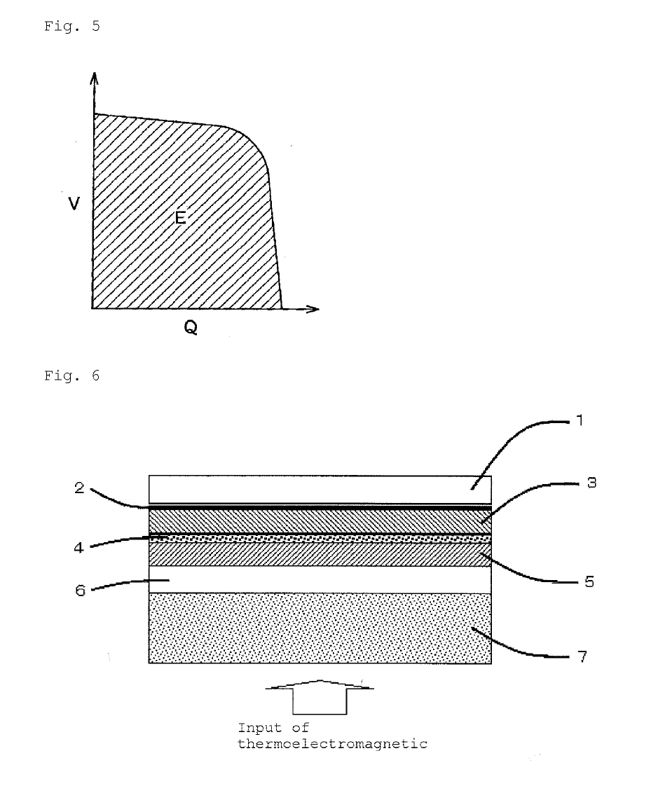

In the secondary battery having such constitution as above, a voltage charged does not rapidly drop as shown in FIG. 5, and discharge of a constant voltage can be continued over a long period of time. At this point, the secondary battery is different in properties from a capacitor in which a voltage rapidly drops with discharge.

The photoelectric conversion element having a storage/discharge function in which such a secondary battery as above and the photoelectric conversion element are laminated together has constitution shown below.

[Photoelectric Conversion Element Having Storage/Discharge Function]

By using the photoelectric conversion element of the present invention together with the secondary battery, the photoelectric conversion element can be used as a photoelectric conversion element having storage/discharge ability.

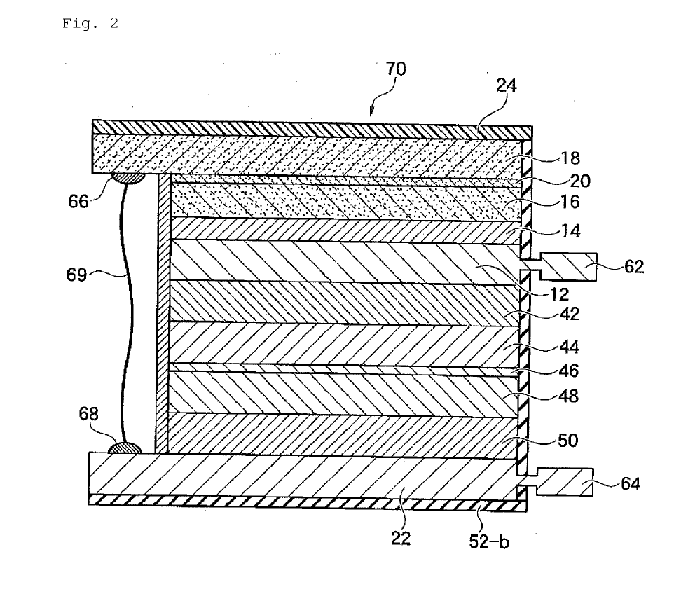

A sectional view of the photoelectric conversion element having storage/discharge ability, which uses the photoelectric conversion element of the present invention shown in FIG. 1, is shown in FIG. 2.

That is to say, the photoelectric conversion ability 70 having storage/discharge ability has constitution in which a secondary battery is arranged on the back surface of the photoelectric conversion element of the present invention and is united to the element.

The substrate layer 12 that is a minus electrode in the photoelectric conversion element 70 having storage/discharge ability is formed of a conductive metal plate. As the conductive metal for forming the substrate layer 12 that is a minus electrode, copper, silver, gold or the like can be used, but from the viewpoint of cost, a copper plate of the aforesaid thickness is preferably used.

From one end of the substrate layer 12 that is a minus electrode, a minus electrode terminal 62 is derived. The substrate layer 12 and the minus electrode terminal 62 are usually formed of the same conductive metal. The thickness of the substrate layer 12 is usually 0.1 to 100 μm.

This substrate layer 12 can be formed by using a copper plate, electroless plating, deposition or the like. When a copper plate is used, a copper foil having a thickness in the range of 1 to 75 μm is preferably used from the viewpoint of handling. When the substrate layer 12 is formed by electroless plating or deposition, the thickness of the substrate layer is preferably in the range of 0.1 to 20 μm. For the electroless plating, an electroless plating solution for copper, which is usually on the market, can be used. When the substrate layer is formed by deposition, deposition methods such as CVD, vacuum deposition and sputtering can be adopted, but it is preferable to form the substrate layer 12 by vacuum deposition. When a deposition method such as vacuum deposition or sputtering is adopted, it is preferable to deposit the metal under reduced pressure in an atmosphere of an inert gas such as nitrogen gas or argon gas while heating the metal to a temperature of not lower than the melting point of the metal. The minus electrode terminal 62 derived from the substrate layer 12 can be formed simultaneously with formation of the substrate layer 12, or after the substrate layer 12 is formed, the minus electrode terminal can be separately derived from the thus formed substrate layer 12 by the use of a conductor.

On a surface of the substrate layer 12 formed as above, a collector electrode 14 is formed in contact with the substrate layer 12. This collector electrode 14 is usually formed of an evaporated film of a bulb metal such as aluminum, stainless steel, chromium, tantalum, niobium or the like. Particularly in the present invention, the collector electrode is preferably a metallic aluminum evaporated layer. The thickness thereof is usually in the range of 0.1 to 0.3 μm. By forming a metallic aluminum layer having a thickness in such a range as above as the collector electrode 14, minus charge generated in an n-type compound semiconductor layer 16 to be laminated on the collector electrode 14 can be favorably accumulated on the substrate layer 14.

The collector electrode 14 in the photoelectric conversion element 70 having storage/discharge ability can be formed by a deposition method using metallic aluminum. When the collector electrode 14 is formed by adopting a deposition method such as vacuum deposition, it is preferable to deposit aluminum under reduced pressure in an atmosphere of an inert gas such as nitrogen gas or argon gas while heating aluminum to a temperature of not lower than the melting point of aluminum at that atmospheric pressure.

On a surface of the thus formed collector electrode 14, an n-type compound semiconductor layer 18 can be directly formed, but adhesion of the n-type compound semiconductor 18 to the collector electrode 14 is not always good, so that it is preferable to interpose a layer containing carbon (not shown in the drawing). It is preferable that the n-type compound semiconductor layer is formed through at least one layer selected from the group consisting of a graphene layer, a graphite layer and a carbon nanotube layer, as the layer containing carbon. Here, the graphene layer is a single layer of carbon atom, and a graphite layer wherein at least a part of the graphene layer becomes a multilayer may be used, or a layer made of carbon nanotube that is a tube formed of carbon atoms may be used. In particular, the layer containing carbon is preferably a graphene layer formed of a carbon single layer. Therefore, the mean thickness of the layer containing carbon is usually in the range of 0.01 to 10 nm. The graphene layer has only to be formed on at least a part of the surface of the collector electrode 14. Although the graphene layer is preferably formed all over the surface, the whole surface of the collector electrode 14 does not necessarily have to be coated with the graphene layer because the graphene layer is a carbon single layer.

In the photoelectric conversion element 70 having storage/discharge ability, on a surface of the collector electrode 14 where such a graphene layer as above has been preferably formed, an n-type compound semiconductor layer 18 is formed.

The dielectric composition containing a fullerene, which forms the n-type compound semiconductor layer 18 and is used in the photoelectric conversion element 70 having storage/discharge ability, preferably contains at least C₆₀ fullerene and/or C₇₀ fullerene, a conductive polymer and an organic pigment. Here, as fullerenes other than C₆₀ fullerene and C₇₀ fullerene, there can be mentioned C₆₂, C₆₈, C₈₀, C₈₂ and carbon nanotube (CNT). Further, small gap fullerene (SGF) is also included in C₆₀ fullerene.

In such an n-type compound semiconductor layer 16, it is preferable that regarding at least a part of the fullerene, electron transfer in the n-type compound semiconductor layer is made possible.

In the photoelectric conversion element 70 having storage/discharge ability, it is preferable that at least a part of the fullerene that forms the n-type compound semiconductor layer is contained in the n-type compound semiconductor layer in such a manner that it is capable of molecular rotation.

Examples of the fullerenes for forming the n-type compound semiconductor layer include C₆₀, C₇₀, C₆₂, C₆₈, C₈₀, C₈₂ and carbon nanotube (CNT), and specific examples thereof are shown below.

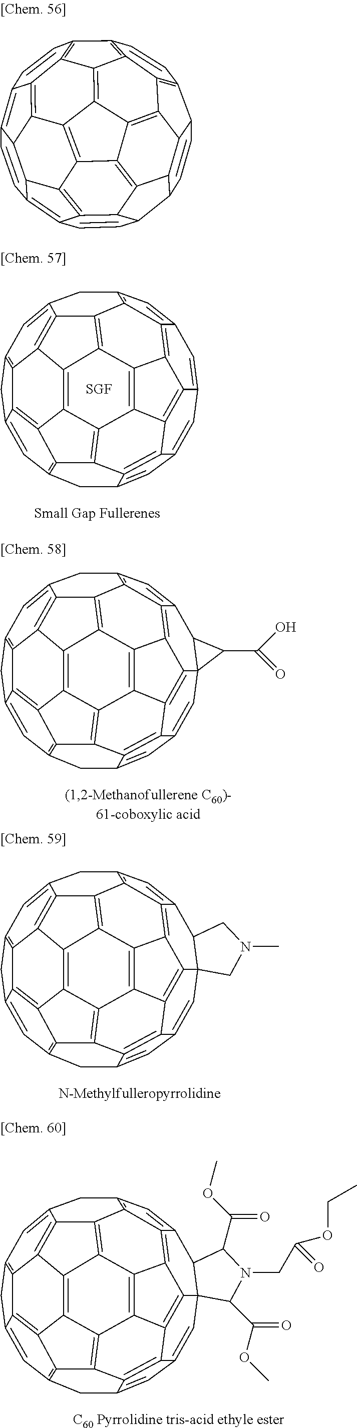

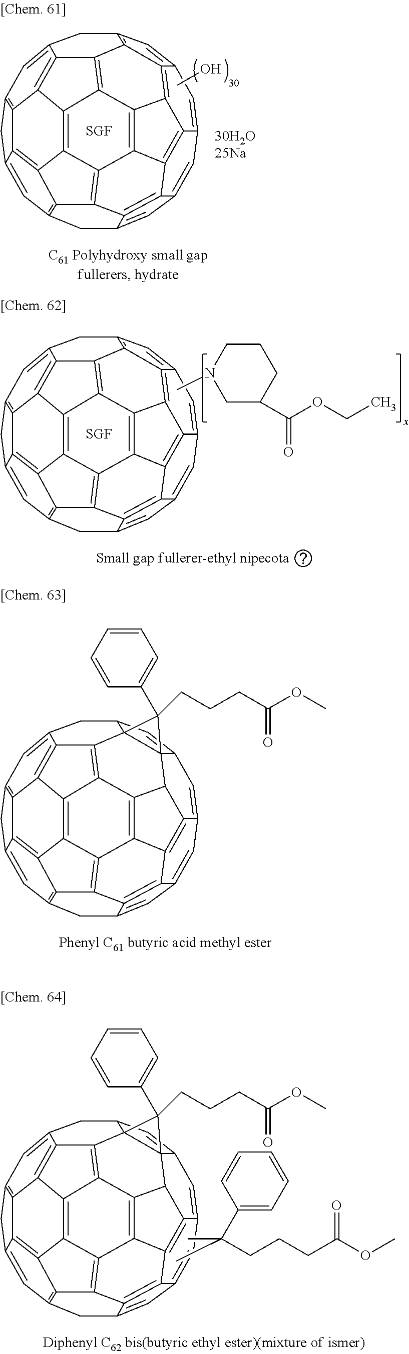

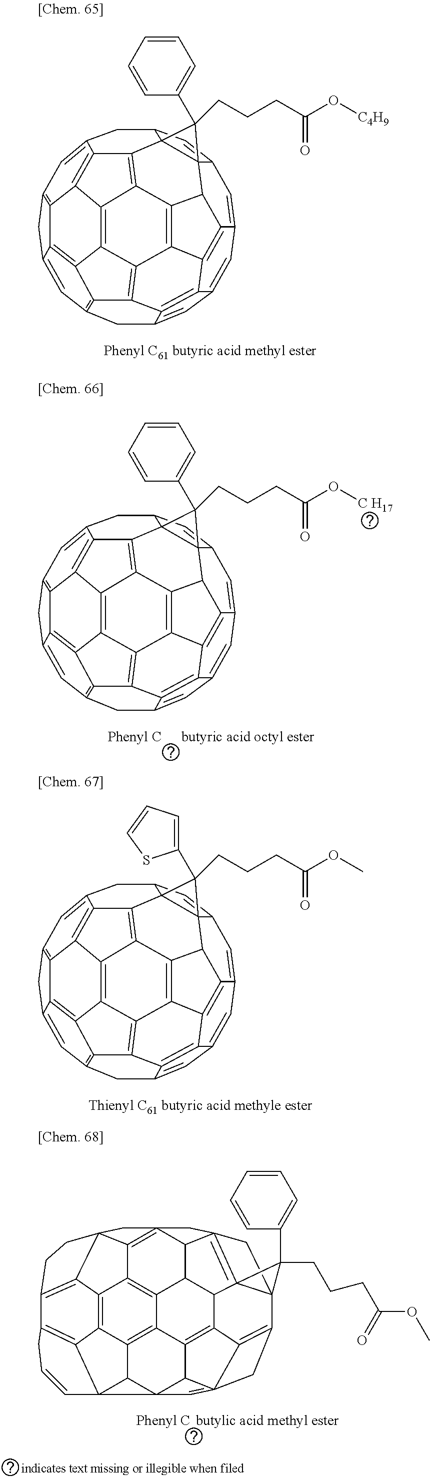

In particular, it is preferable to use C₆₀ fullerene, C₇₀ fullerene and modified products thereof singly or in combination.

Such fullerenes as above may be doped or intercalated with other elements. Examples of such elements include K and Ba. The elements for doping or intercalation are not limited to the above elements.

Such a fullerene as above may be an including fullerene that includes a metal atom in its hollow skeleton. Examples of such fullerenes include fullerene including potassium, fullerene including scandium, fullerene including lanthanum, fullerene including cesium, fullerene including titanium, fullerene including cesium/carbon, fullerene including cesium/nitrogen, C₈₀ fullerene including uranium, and C₈₂ fullerene including two uranium atoms. The including fullerenes are not limited to the above ones. Such including fullerenes exhibit extremely high electrical conduction property.

In the photoelectric conversion element 70 having storage/discharge ability, the dielectric composition for forming the n-type compound semiconductor layer 16 contains a conductive polymer in addition to the above fullerene. In the present working example, polyaniline or polythiophene is compounded as the conductive polymer.

Examples of other conductive polymers used herein include polyacetylene, poly(p-phenylenevinyl), polypyrrole, poly(p-phenyl sulfide), 5,5-dihexyl-2,2′-bithiophene (DH-2T), 2,2′,5,2″-trithiophene, α-quaterthiophene (4T), 3,3′″-dihexyl-2,2′,5′,2,5″,2′″-quaterthiophene (DH-4T), 3,3′″-didodecyl-2,2′:2″:5′,2″:5″,2′″-quaterthiophene, α-sexithiophene (6T), α,ω-dihexylsexithiophene (DH-6T), 5,5′-di(4-biphenylylyl)-2,2′-bithiophene, 5,5′-bis(2-hexyl-9H-fluoren-7-yl)-2,2′-bithiophene (DHFTTF), poly(3-hexylthiophene-2,5-diyl) (P3HT), poly(3-octylthiophen-2,5-yl (P30T), poly(3-dodecylthiophen-2,5-yl) (P3DDT), poly[2-methoxy-5-(3′,7′-dimethyloctyloxy)-1,4-phenylenevinylene] (MDMP-PPV), poly[methoxy-5-(2-ethylhexyloxy)]-1,4-phenylenevinylene (MEH-PPV), poly[bis(4-phenyl)(2,4,6-trimethylphenylamine) (PTAA), poly[9,9-dioctylfluorenyl-2,7-diyl]-co-bithiophene (F8T2) and poly(3-octylthiophene-2,5-diyl-co-desiloxythiophene-2,5-diyl) (POT-co-DOT). In the present invention, the conductive polymers are not limited to these polymers. In the present invention, these can be used singly or in combination. Particularly in the present invention, polythiophene, α,ω-dihexylsexithiophene (DH-6T) and polyaniline are preferably used singly or in combination.

In the photoelectric conversion element 70 having storage/discharge ability, the dielectric composition for forming the n-type compound semiconductor layer 16 contains an organic pigment.

The organic pigment used herein may be an organic pigment itself or may be an organic pigment (latent pigment) converted from a precursor of an organic pigment. As the latent pigment used herein, there can be mentioned a precursor described in U.S. Pat. No. 6,071,989 (patent literature 4). Specifically, a compound represented by the following formula (1) can be mentioned.

A(B)ₓ (1)

In the above formula (1), x is an integer of 1 to 8, and when x is 2 to 8, each B may be the same or different.

In the formula (1), A represents a radical of anthraquinone-based, azo-based, benzimidazolone-based, quinacridone-based, quinophthalone-based, diketopyrrolopyrrole-based, dioxazine-based, indanthrone-based, indigo-based, isoindoline-based, isoindolinone-based, perylene-based or phthalocyanine based chromophore. A in the formula (1) is bonded to B through a hetero atom of A, such as N, O or S.

In the formula (1), B represents a radical selected from the group consisting of the following formulas (2), (3), (4), (5a) and (5b).

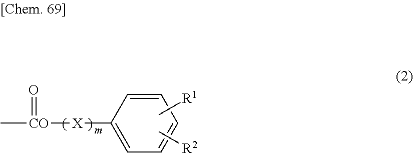

In the above formula (2), m represents 0 or 1. X represents an alkenyl group of 2 to 5 carbon atoms, which is unsubstituted or may be substituted by an alkyl group of 1 to 6 carbon atoms or R⁵ or R⁶, or an alkylene group of 1 to 65 carbon atoms. Here, R⁵ and R⁶ each independently represent a hydrogen atom, an alkyl group of 1 to 24 carbon atoms, an alkyl group of 1 to 24 carbon atoms in which O is inserted, S is inserted, or an alkyl group of 1 to 6 carbon atoms di-substitutes and N is inserted, an alkenyl group of 3 to 24 carbon atoms, an alkynyl group of 3 to 24 carbon atoms, a cycloalkanyl group of 4 to 12 carbon atoms, or a phenyl or biphenyl group which is unsubstituted or substituted by an alkyl group of 1 to 6 carbon atoms, an alkoxy group of 1 to 6 carbon atoms, a halogen group, a cyano group or a nitro group. In the present invention, the expression “a group such as O, S or N is inserted in an alkyl group” means that the alkyl group contains such a group in the middle of its carbon chain.

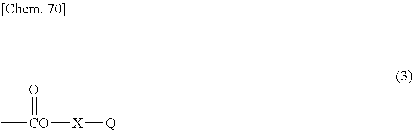

In the formula (3), X represents an alkenyl group of 2 to 5 carbon atoms, which is unsubstituted or may be substituted by an alkyl group or 1 to 6 carbon atoms or R⁵ or R⁶, or an alkylene group of 1 to 6 carbon atoms, and Q represents a hydrogen atom, an alkyl group of 1 to 6 carbon atoms, CN group, CCl₃ group, a group shown below, SO₂CH₃ or SCH₃. R⁵ and R⁶ have the same meanings as those in the formula (2).

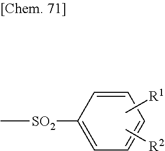

In the above formula, R¹ and R² have the same meanings as those in the formula (2).

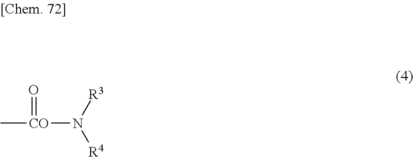

In the formula (4), R³ and R⁴ are each independently a halogen group, an alkyl group of 1 to 4 carbon atoms or a group represented by the following formula. In the formula (4), R³ and R⁴ may be bonded to each other to form a piperidinyl group.

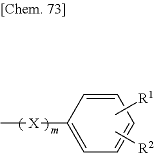

In the above formula, m, X, R¹ and R² have the same meanings as those in the formula (2).

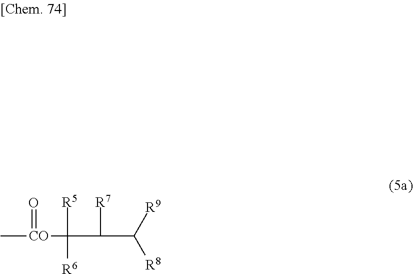

In the formula (5a), R⁵ and R⁶ each independently represent a hydrogen atom, an alkyl group of 1 to 24 carbon atoms, an alkyl group of 1 to 24 carbon atoms in which O is inserted, S is inserted, or an alkyl group of 1 to 6 carbon atoms di-substitutes andN is inserted, an alkenyl group of 3 to 24 carbon atoms, an alkynyl group of 3 to 24 carbon atoms, a cycloalkanyl group of 4 to 24 carbon atoms, or a phenyl or biphenyl group which is unsubstituted or substituted by an alkyl group of 1 to 6 carbon atoms, an alkoxy group of 1 to 6 carbon atoms, a halogen group, a cyano group or a nitro group.

In the formula (5a), further, R⁷, R⁸ and R⁹ each independently represent a hydrogen atom, an alkyl group of 1 to 24 carbon atoms or an alkenyl group of 3 to 24 carbon atoms.

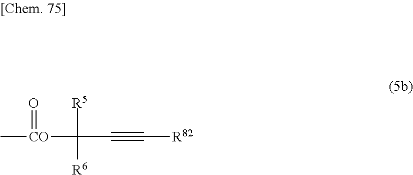

In the formula (5b), R⁵ and R⁶ each independently represent a hydrogen atom, an alkyl group of 1 to 24 carbon atoms, an alkyl group of 1 to 24 carbon atoms in which O is inserted, S is inserted, or an alkyl group of 1 to 6 carbon atoms di-substitutes andN is inserted, an alkenyl group of 3 to 24 carbon atoms, an alkynyl group of 3 to 24 carbon atoms, a cycloalkanyl group of 4 to 24 carbon atoms, or a phenyl or biphenyl group which is unsubstituted or substituted by an alkyl group of 1 to 6 carbon atoms, an alkoxy group of 1 to 6 carbon atoms, a halogen group, a cyano group or a nitro group. In the formula (5b), further, R⁸² represents an alkyl group or any one of the following groups.

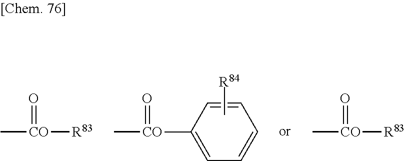

In the above formulas, R⁸³ represents an alkyl group of 1 to 6 carbon atoms, R⁸⁴ represents a hydrogen atom or an alkyl group of 1 to 6 carbon atoms, and R⁸⁵ represents an alkyl group, or a phenyl group which is unsubstituted or substituted by an alkyl group of 1 to 6 carbon atoms.

In the aforesaid formula (1), B represents a group represented by the following formula.

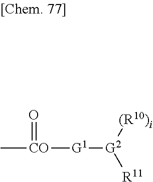

Here, G¹ represents a p, q-alkylene group of 2 to 12 carbon atoms, which is unsubstituted or substituted by a saturated hydrocarbon group of 1 to 12 carbon atoms, an alkoxy group of 1 to 12 carbon atoms, an alkylthio group of 1 to 12 carbon atoms or a dialkylamino group of 2 to 24 carbon atoms. Here, p and q represent position numbers different from each other, and the alkylene group may be substituted by one substituent or may be substituted by two or more substituents.

G² represents any one hetero atom selected from the group consisting of N, O and S. When G² is O or S, i is 0. When G² is N, i is 1.

R¹⁰ and R¹¹ each independently represent [(p′,q′-alkyl group of 2 to 12 carbon atoms)-R¹²]ᵢᵢ-(alkyl group of 1 to 12 carbon atoms) {namely, a group wherein ii repeating structures, in each of which P′,q′-alkyl group of 2 to 12 carbon atoms and R¹² are bonded to each other, are bonded, and alkyl group of 1 to 12 carbon atoms is bonded at the end on the R¹² side}, or an unsubstituted or substituted alkyl group of 1 to 12 carbon atoms.

Examples of the substituents of the alkyl group of 1 to 12 carbon atoms include an alkoxy group of 1 to 12 carbon atoms, an allylthio group of 1 to 12 carbon atoms, an allylthio group of 6 to 12 carbon atoms, a dialkylamino group of 2 to 24 carbon atoms, an allylthio group of 6 to 12 carbon atoms, an alkylallylamino group of 7 to 24 carbon atoms and a diallylamino group of 12 to 24 carbon atoms. The alkyl group may be substituted by one substituent or may be substituted by two or more substituents.

The above ii represents a number of 1 to 1000, and p′ and q′ represent position numbers different from each other. Each R¹² represents O, S, or N substituted by an alkyl group or represents an alkylene group of 2 to 12 carbon atoms. The repeating structure has the same meaning as previously described.

R¹⁰ and R¹¹ may be each saturated or may each have 1 to 10 unsaturated bonds. In each of R¹⁰ and R¹¹, a group such as —(C═O) or —C₆H₄— may be introduced at an arbitrary position. Further, R¹⁰ and R¹¹ may be each unsubstituted or may each have 1 to 10 substituents such as halogen atoms, cyano groups and nitro groups.

However, when -G¹- is —(CH₂)ᵢᵥ—, iv represents an integer of 2 to 12, G² represents S, and R¹¹ is not an unsubstituted or substituted alkyl group of 1 to 4 carbon atoms in which not carbon but 0, S or N is inserted in the middle of the carbon chain.

Another example of the latent pigment used in the photoelectric conversion element 70 having storage/discharge ability of the present invention is a compound represented by the following formula (6).

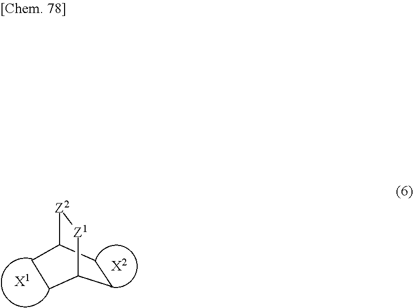

In the formula (6), at least one of X¹ and X² represents a group which forms a π-conjugated divalent aromatic ring, and Z¹-Z² represents a group which is capable of elimination by heat or light so that a π-conjugated compound obtained by elimination of Z¹-Z² may become a pigment molecule, and of X¹ and X², a group which does not form a π-conjugated divalent aromatic ring represents a substituted or unsubstituted ethenylene group.

From the compound represented by the formula (6), Z¹-Z² is eliminated by heat or light to produce a π-conjugated compound having high planarity, as shown by the following chemical reaction. In the present invention, this π-conjugated compound produced becomes an organic pigment to be compounded in the n-type compound semiconductor layer. This organic pigment is a semiconductor.

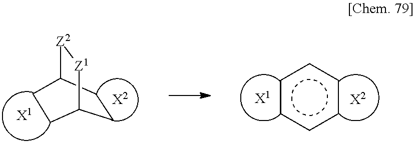

Examples of the compounds represented by the formula (6) include the following compounds.

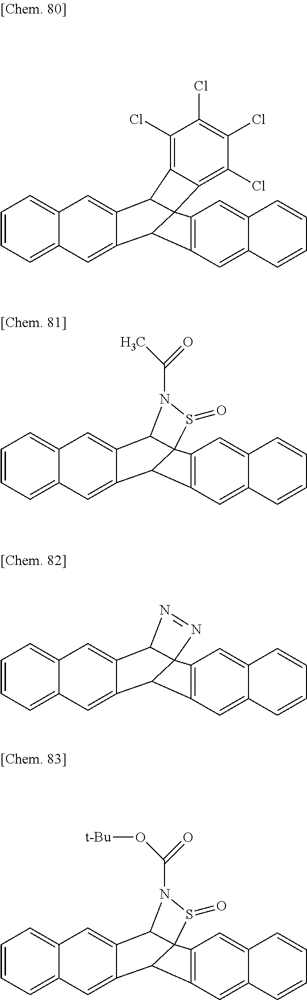 [SMILES: Clc1c(Cl)c(Cl)c2c(c1Cl)C1c3cc4ccccc4cc3C3c4cc5ccccc5cc4C231 ; CC(=O)N1C2c3cc4ccccc4cc3C3c4cc5ccccc5cc4C32S1=O ; c1ccc2cc3c(cc2c1)C1N=NC12c1cc4ccccc4cc1C32 ; CC(C)(C)OC(=O)N1C2c3cc4ccccc4cc3C3c4cc5ccccc5cc4C32S1=O]

By applying light or heat to the above compounds, compounds which have high planarity as shown by, for example, the following formula and are π-conjugated can be obtained from the above latent organic pigments.

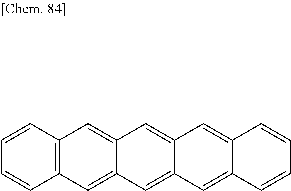 [SMILES: c1ccc2cc3cc4cc5ccccc5cc4cc3cc2c1]

The organic pigment has low dispersibility in a solvent similarly to a fullerene, and it is difficult to produce a dielectric composition of high homogeneity, which contains a fullerene, a conductive polymer and an organic pigment and forms the n-type compound dielectric layer 16 in the present invention. However, by dispersing such a precursor as above in a dispersion medium to form a homogeneous composition and then heating the composition, an organic pigment is produced from the precursor, whereby a dielectric composition having high homogeneity can be obtained.

Examples of the organic pigments to be contained in the dielectric composition for forming the n-type compound semiconductor layer include phthalocyanine (H₂Pc) and its metal complexes; tetrabenzoporphyrin and its metal complexes; tetracene (naphthacene); polyacenes, such as pentacene, pyrene and perylene; perfluoro compounds of organic pigments, e.g., oligothiophenes such as sexithiophene; and aromatic carboxylic anhydrides and imidization products thereof, such as naphthalenetetracarboxylic anhydride, napthalenetetracarboxylic acid diimide, perylenetetracarboxylic anhydride and perylenetetracarboxylic acid diimide, and derivatives having these compounds as skeletons. These can be used singly or in combination. Examples of the precursors of the organic pigments for forming the n-type compound dielectric layer are shown below.

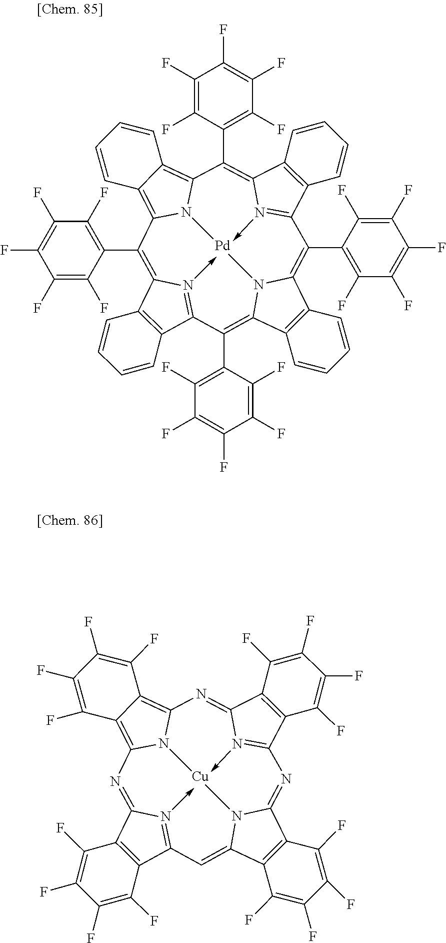

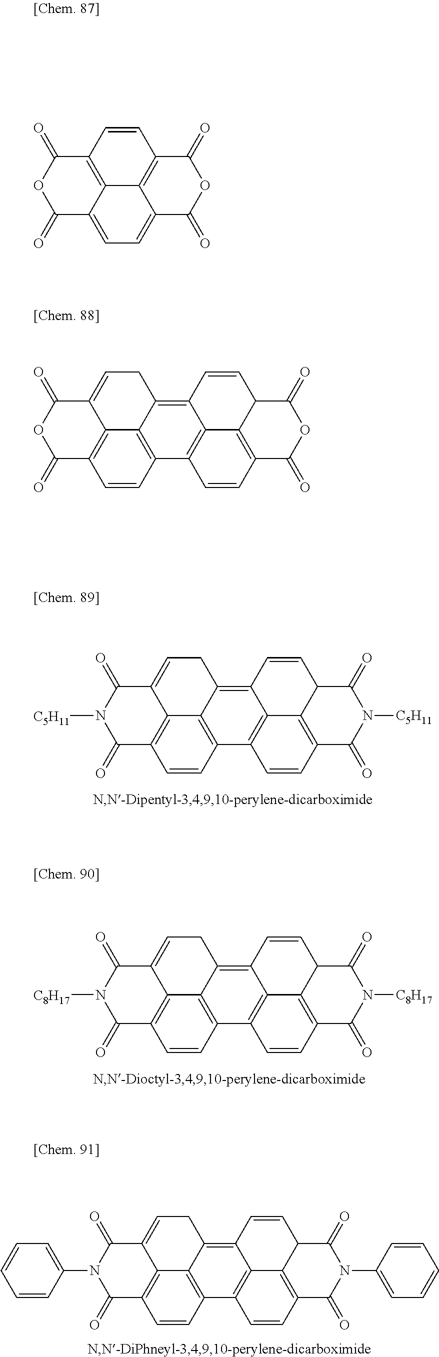

Such an organic pigment precursor as above is converted into an organic pigment by dissolving or dispersing it in a polar solvent such as N-methyl-2-pyrrolidone (NMP) or chloroform and heating the solution or the dispersion usually at a temperature of not lower than 100° C., preferably at a temperature of not lower than 150° C., usually for not shorter than 30 seconds, preferably for not shorter than 1 minute. In the thermal conversion into the organic pigment, the upper limit of the heating temperature and the upper limit of the heating time are not specifically restricted, but thermal decomposition of the organic pigment begins at, for example, a temperature of about 400° C., and even if the organic pigment precursor is heated for longer than 100 hours, an effect due to the prolonged heating time is not obtained.

An example of the reaction to form an organic dye from the organic dye precursor by heating is shown below.

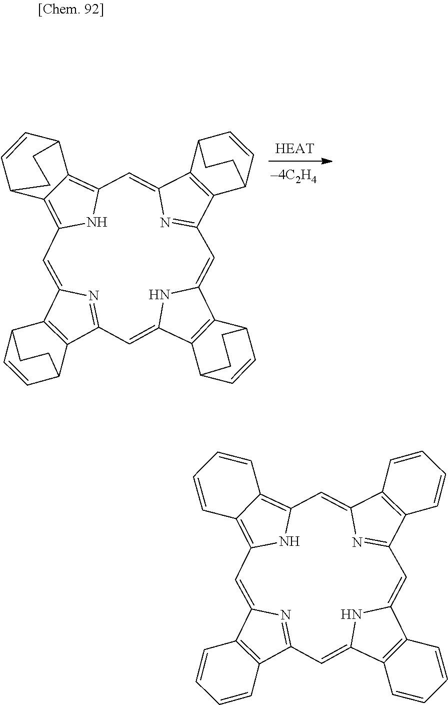 [SMILES: C1=CC2CCC1C1=C2c2cc3[nH]c(cc4nc(cc5[nH]c(cc1n2)c1c5C2C=CC1CC2)C1=C4C2C=CC1CC2)c1c3C2C=CC1CC2 ; c1ccc2c(c1)-c1cc3[nH]c(cc4nc(cc5[nH]c(cc-2n1)c1ccccc51)-c1ccccc1-4)c1ccccc31]

The above thermal conversion is usually carried out in an atmosphere of an inert gas such as nitrogen gas or argon gas.

With regard to the compounding ratio between the fullerene, the conductive polymer and the organic pigment in the dielectric composition used herein, the fullerene is usually used in an amount of 1 to 10 parts by weight, the conductive polymer is usually used in an amount of 1 to 10 parts by weight, and the organic pigment is usually used in an amount of 1 to 10 parts by weight, each being based on the total of these three components.

In the present invention, the n-type semiconductor layer can be also formed from C₆₀ fullerene, graphene, phthalocyanine (H₂Pc), molybdenum oxide, etc. which are n-type nanocarbon materials. An SEM photograph (40000 magnifications) of n-type nanocarbon materials of such components as above is shown in FIG. 9.

The dielectric composition of such constitution is laminated on the collector electrode 14, preferably on the graphene layer formed on the surface of the collector electrode 14, to form the n-type compound semiconductor layer 16. The thickness of the n-type compound semiconductor layer 16 is usually 1 to 10 μm, preferably 1 to 2 μm.

The method for forming the n-type compound semiconductor layer 16 is not specifically restricted. Although the dielectric composition may be dissolved or dispersed in a solvent and applied by a publicly known method such as spin coating or casting, the n-type compound semiconductor layer can be also formed by depositing the dielectric composition. In this case, CVD, vacuum deposition, sputtering or the like can be adopted, and it is preferable to form the n-type compound semiconductor layer by deposition or casting under the conditions of an inert gas.

After the n-type compound semiconductor layer 16 is formed as above, a p-type compound semiconductor layer 18 can be formed in such a manner that this layer comes into contact with the surface of the n-type compound semiconductor layer 16. However, it is preferable that a pn-bulk layer 20 is intermittently formed on the surface of the n-type compound semiconductor layer 16, and thereafter, the p-type compound semiconductor layer 18 is formed. This pn-bulk layer is a layer which is formed of a ferroelectric substance and in which electrons that are carriers and positive holes that are carriers are balanced. This pn-bulk layer 20 is intermittently in contact with both of the p-type compound semiconductor layer 18 and the n-type compound semiconductor layer 18.

The pn-bulk layer 20 can be formed by intermittently depositing a ferroelectric, such as lead titanate, lead(II) zirconate titanate or strontium titanate, on the surface of the n-type semiconductor layer 18.

The mean thickness of the pn-bulk layer 20 is usually 1 to 2 μm, and this layer is intermittently formed on the surface of the n-type compound semiconductor layer 16, so that this layer is intermittently in contact with not only the n-type compound semiconductor layer 16 but also the p-type compound semiconductor layer 20. The n-type compound semiconductor layer 18 is also in contact with the p-type compound semiconductor layer 20 through gaps of the pn-bulk layer.

By forming the pn-bulk layer 20 as above, the fullerene contained in the n-type compound semiconductor layer 16 is always in contact with the pn-bulk layer 20. In the n-type compound semiconductor layer 16, the fullerene is rotating at a high speed, and the rotation vibration of the fullerene acts on the ferroelectric component of the pn-bulk layer 20, and by virtue of the piezoelectric effect, electromotive force is generated also in the pn-bulk layer 20. In the present invention, the electromotive force generated by the piezoelectric effect is also used.

In the photoelectric conversion element 70 having storage/discharge ability, the pn-bulk layer 20 is formed as above, and on the pn-bulk layer, the p-type compound semiconductor layer 18 is formed.

The p-type compound semiconductor layer 18 is preferably a transparent evaporated film formed from an oxide comprising silicon dioxide containing a dopant that forms a positive hole. As the dopant that forms a positive hole, phosphorus, boron or the like can be mentioned. Such a dopant is used in an amount of 0.1 to 10 parts by weight based on 100 parts by weight of silicon dioxide. If silicon dioxide is doped with such a dopant, a positive hole is formed in the p-type compound semiconductor layer 18 formed of silicon dioxide, and the positive hole thus formed looks as if it could freely transfer in the p-type compound semiconductor layer 18.

The p-type compound semiconductor layer 18 can be also formed from polyaniline and graphene. An example of an SEM photograph of the p-type compound semiconductor layer formed from polyanilien and graphene is shown in FIG. 8. The magnifications of the SEM photograph are 20000.

The p-type compound semiconductor layer 18 usually has a thickness of 1 to 2 μm. Such a p-type compound semiconductor layer 18 can be formed by deposition. When the p-type compound semiconductor layer is formed by a deposition method, the layer can be formed by using silicon dioxide containing the dopant and by adopting CVD, vacuum deposition, sputtering or the like, and it is preferable to carry out deposition under the conditions of an inert gas.

The p-type compound semiconductor layer 18 can be also formed by a casting method.

On the p-type compound semiconductor layer 18, a pump 66 is formed at the position corresponding to a bump 68 formed on a plus electrode 22 of a secondary battery that is provided under the photoelectric conversion element.

In the present invention, it is enough just to form the above layers in this order, but there is no specific limitation on the order of formation, and the order of formation may be reversed.

Although the photoelectric conversion element 70 having storage/discharge ability has such constitution as above, it is preferable to form a surface protective layer 24 on a surface of the p-type compound semiconductor layer. This surface protective layer 24 is formed of a polymer film or sheet, and when the photoelectric conversion element 70 having storage/discharge ability is used as a flexible photoelectric conversion element, the thickness of this surface protective layer 24 is usually set to 50 to 300 μm. By virtue of such a thickness, the surface of the p-type compound semiconductor layer 18 is protected by the surface protective layer 24, and besides, the photoelectric conversion element 70 having storage/discharge ability of the present invention can be handled as a flexible film. By compounding infrared conversion particles in the surface protective layer 24 within limits not detrimental to the transparency of the surface protective layer, not only visible rays but also rays that are not attributable to sunlight, such as infrared rays and far infrared rays, can be captured. Therefore, power generation not attributable to visible light becomes feasible.

In FIG. 4, an example of a light absorption band of a photoelectric conversion element obtained when (far) infrared-emitting inorganic particles are compounded in the surface protective layer as the infrared conversion particles is shown.

As a matter of course, the photoelectric conversion element 70 having storage/discharge ability can absorb visible light to generate power as described above, and it can absorb also light of infrared region of a wavelength of 7 μm to 14 μm to effectively generate power, as shown in FIG. 4.

Storage/discharge of power in the photoelectric conversion element 70 having storage-discharge ability of the present invention is carried out by a secondary battery having constitution including the collector electrode 14 and the substrate layer 12.

Current flows as above, and as a result, a difference in temperature occurs between the front surface and the back surface of a cell of the photoelectric conversion element of the present invention. This difference in temperature allows the photoelectric conversion element to generate electromotive force by virtue of Seebeck effect, and in the present invention, therefore, electromotive force attributable to the Seebeck effect can be also utilized.

In the photoelectric conversion element 70 having storage/discharge ability, a secondary battery minus electrode face 42 is laminated on a surface of the substrate layer 12 where the collector electrode 14 is not provided. The secondary battery minus electrode face 42 is preferably formed from an oxide comprising silicon dioxide. Here, the main component of the oxide to form the secondary battery minus electrode face is silicon dioxide, and the silicon dioxide is usually doped with a dopant. The dopant used herein facilitates accumulation of minus charge, which has been generated in the n-type compound semiconductor 16, on a ferroelectric layer (first electrolyte layer) 42 described later, and examples of such dopants include Br and I. Such a dopant is used usually in an amount of 0.001 to 10 parts by weight based on 100 parts by weight of silicon dioxide. By using the dopant in such an amount as above, minus charge generated in the n-type compound semiconductor layer 16 can be efficiently transferred.

Such a secondary battery minus electrode face 42 can be usually formed by depositing silicon dioxide containing a dopant, when needed. For the deposition, CVD, vacuum deposition, sputtering or the like can be adopted, but in particular, it is preferable to carry out vacuum deposition in an inert gas. The deposition temperature is usually 350 to 500° C., preferably 350 to 450° C., and as the inert gas, nitrogen gas, argon gas or the like can be used.

The thickness of the secondary battery minus electrode face 42 formed as above is usually 0.1 to 100 μm.

On such a secondary battery minus electrode face 42, a ferroelectric layer (first electrolyte layer) 44 is laminated. In the ferroelectric layer 44 in the photoelectric conversion element 70 having storage/discharge ability, a water-soluble electrolytic solution is not used. In the photoelectric conversion element 70 having storage/discharge ability, a nonaqueous electrolyte containing an ionic liquid electrolyte is used as the electrolyte. Such nonaqueous electrolytes can be used singly or in combination. By using such a nonaqueous electrolyte, corrosion of the secondary battery can be effectively prevented.

Examples of the ionic liquids that are nonaqueous electrolytes include the following salts each consisting of a cation and an anion.

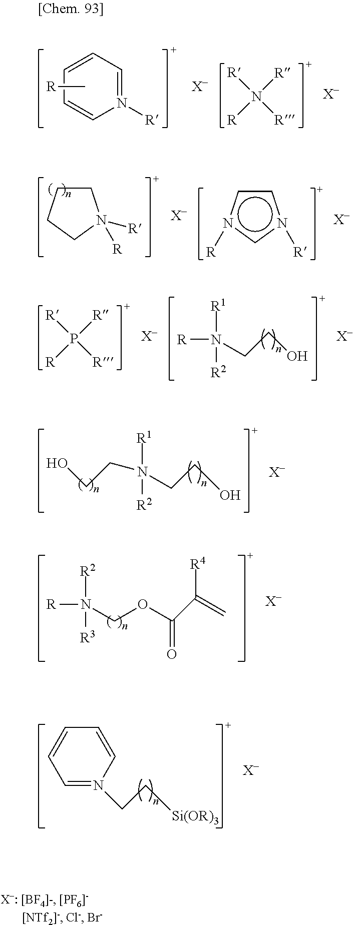

For the nonaqueous electrolyte for forming the ferroelectric layer 44 in the photoelectric conversion element 70 having storage/discharge ability, ammonium-based ions, such as imidazolium salt and pyridinium salt, or phosphonium-based ions are preferably used, and as the anions, halogen-based ions, such as bromide ion and triflate, boron-based ions, such as tetraphenyl borate, and phosphorus-based ions, such as hexafluorophosphate ion, are preferably used in proper combination.

In the ferroelectric layer 44 of the photoelectric conversion element 70 having storage/discharge ability, a cationic polymer electrolyte and/or an anion molecule electrolyte may be contained in addition to the above ionic liquid.

Examples of the anionic polymer electrolytes that are anionic electrolytes and the cationic polymer compounds that are cationic electrolytes include polymer compounds, such as perfluorosulfonic acid polymer, poly(allylbiguanido-co-allylamine) (PAB) and poly(allyl-N-carbamoylguanidino-co-allylamine) (PAC).

In this ferroelectric layer, at least one ferroelectric selected from the group consisting of lead titanate, lead(II) zirconate titanate and strontium titanate is contained as a ferroelectric.

In the ferroelectric layer 44 of the photoelectric conversion element 70 having storage/discharge ability, a general-purpose resin, such as polyolefin, polyester, polyether, polyamide, polyamidoimide or polyimide, may be compounded within limits not detrimental to the properties of the ferroelectric layer 44. The amount of such a general-purpose resin compounded is usually less than 50 parts by weight when the amount of the components for forming the ferroelectric layer 44 is 100 parts by weight.

The ferroelectric layer 44 in the photoelectric conversion element 70 having storage/discharge ability contains a ferroelectric, and contains, if necessary, such an ionic liquid as above and an anionic electrolyte and/or a cationic electrolyte. The ferroelectric layer 44 can be formed by applying a solution or a dispersion, which contains, if necessary, the ionic liquid, the electrolyte, etc. in amounts not detrimental to the properties of the ferroelectric layer 44. The thickness of the ferroelectric layer thus formed is usually in the range of 1 to 100 μm.

In the photoelectric conversion element 70 having storage/discharge ability, the ferroelectric layer 44 having such constitution as above is laminated on an ion supply substance layer 48 through a solid electrolyte layer 46.

In the photoelectric conversion element 70 having storage/discharge ability, the solid electrolyte layer 46 is a layer formed so that it may part the ferroelectric layer 44 from an ion supply substance layer 48 and electrons can transfer from the layer but the electrolyte cannot transfer from the layer, and for example, there can be used a reverse osmosis membrane (RO membrane), an ion exchange resin membrane, or a layer formed from a paste kneadate obtained by kneading an ion conductive substance of an amorphous structure containing a vanadate or the like as a main component with paraffin wax or the like as an adhesive. Such a solid electrolyte layer 46 may be formed by coating the surface of the ferroelectric layer 44 with a coating liquid obtained by dissolving or dispersing a resin having reverse osmosis property or an ion exchange resin in a solvent or the paste kneadate prepared as above using a publicly known method, or may be formed by laminating a membrane that has been separately formed in advance using the coating liquid.

The thickness of the solid electrolyte layer 46 thus formed is usually in the range of 0.01 to 100 μm, preferably 0.1 to 100 μm, particularly preferably 1 to 100 μm. By setting the thickness of the solid electrolyte layer 46 as above, the secondary battery can be efficiently used in the photoelectric conversion element 70 having storage/discharge ability, and besides, occurrence of short circuit can be effectively prevented.

On a surface of such a solid electrolyte layer 46 as above where the ferroelectric layer 44 is not provided, an ion supply substance layer 48 is laminated.

In the ion supply substance layer 48 in the photoelectric conversion element 70 having storage/discharge ability, a water-soluble electrolytic solution is not used. In the photoelectric conversion element 70 having storage/discharge ability of the present invention, a nonaqueous electrolyte containing an ionic liquid electrolyte is used as the electrolyte. Such nonaqueous electrolytes can be used singly or in combination. By the use of such a nonaqueous electrolyte, corrosion of the secondary battery can be effectively prevented.

Examples of the ionic liquids that are nonaqueous electrolytes include the following salts each consisting of a cation and an anion.

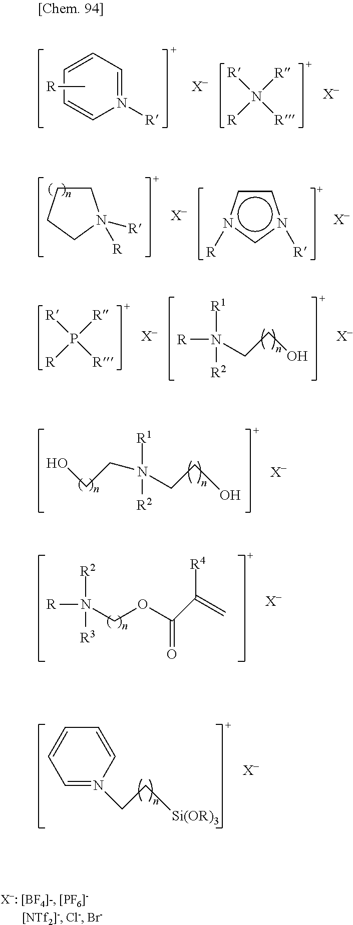

In the photoelectric conversion element 70 having storage/discharge ability, a cationic polymer electrolyte and/or an anion molecule electrolyte may be contained in addition to the above ionic liquid.

Examples of the anionic polymer electrolytes that are anionic electrolytes and the cationic polymer compounds that are cationic electrolytes include polymer compounds, such as perfluorosulfonic acid polymer, poly(allylbiguanido-co-allylamine) (PAB) and poly(allyl-N-carbamoylguanidino-co-allylamine) (PAC).

In the present invention, halides of alkali metals, such as KCl, NaCl and LiCl, can be also used for the ion supply substance layer 48. When such a halide of an alkali metal is used as the ion supply substance, the halide of an alkali metal, and graphene, graphite, carbon nanotube or the like are ground in a solid phase, then the resulting powder is dispersed in an organic solvent such as N-methyl-2-pyrrolidone (NMP) to prepare a casting liquid, the casting liquid is cast, then the organic solvent is removed to form a cast layer, and this cast layer can be used. When such a halide of an alkali metal as above is used, the potential of the storage layer usually varies as follows depending upon the alkali metal used.

Potassium (K): −2.925 V

Sodium (Na): −2.714 V

Lithium (Li): −3.045 V

For the nonaqueous electrolyte for forming the ion supply substance layer 48 of the photoelectric conversion element 70 having storage/discharge ability, ammonium-based ions, such as imidazolium salt and pyridinium salt, or phosphonium-based ions are preferably used, and as the anions, halogen-based ions, such as bromide ion and triflate, boron-based ions, such as tetraphenyl borate, and phosphorus-based ions, such as hexafluorophosphate ion, are preferably used in proper combination.

The ion supply substance layer 48 of the photoelectric conversion element 70 having storage/discharge ability contains an ion supply substance, and contains, if necessary, a cationic polymer electrolyte and/or an anion molecule electrolyte in addition to such an ionic liquid as above.

Examples of the anionic polymer electrolytes that are anionic electrolytes and the cationic polymer compounds that are cationic electrolytes include polymer compounds, such as perfluorosulfonic acid polymer, poly(allylbiguanido-co-allylamine) (PAB) and poly(allyl-N-carbamoylguanidino-co-allylamine) (PAC).

In the ion supply substance layer 48 of the photoelectric conversion element 70 having storage/discharge ability, a general-purpose resin, such as polyolefin, polyester, polyether, polyamide, polyamidoimide or polyimide, may be compounded within limits not detrimental to the properties of the ion supply substance layer 48. The amount of such a general-purpose resin compounded is usually less than 50 parts by weight when the amount of the components for forming the ion supply substance layer 48 is 100 parts by weight.

The ion supply substance layer 48 in the photoelectric conversion element 70 having storage/discharge ability contains an ion supply substance, and contains, if necessary, such an ionic liquid as above and an anionic electrolyte and/or a cationic electrolyte. The ion supply substance layer 48 can be formed by applying a solution or a dispersion, which contains, if necessary, the ionic liquid, the electrolyte, etc. in amounts not detrimental to the properties of the ion supply substance layer 48. The thickness of the second electrolyte layer thus formed is usually in the range of 0.01 to 100 μm.

The ferroelectric layer 44 has composition containing a ferroelectric as an essential component, while the ion supply substance layer 48 contains an ion supply substance as an essential component, and the compositions of these layers are usually different as described above, but they may be the same as each other.

On a surface of such an ion supply substance layer 48 as above where the solid electrolyte layer 46 is not laminated, a secondary battery plus electrode face 50 is formed.

This secondary battery plus electrode face 50 is formed from at least one carbon material selected from the group consisting of fullerenes, graphene and carbon nanotube (CNT).

As the fullerenes for use herein, the same fullerenes as the aforesaid ones can be used. Examples of such fullerenes include the following fullerenes.

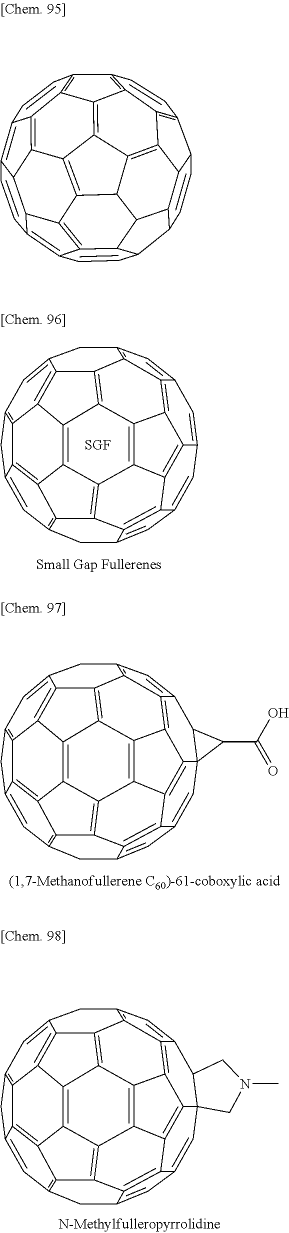

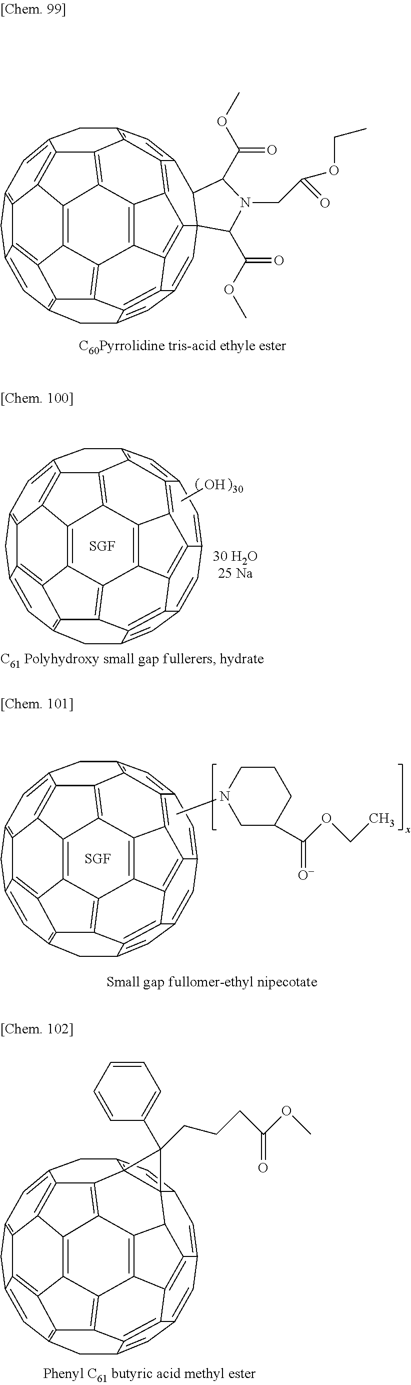

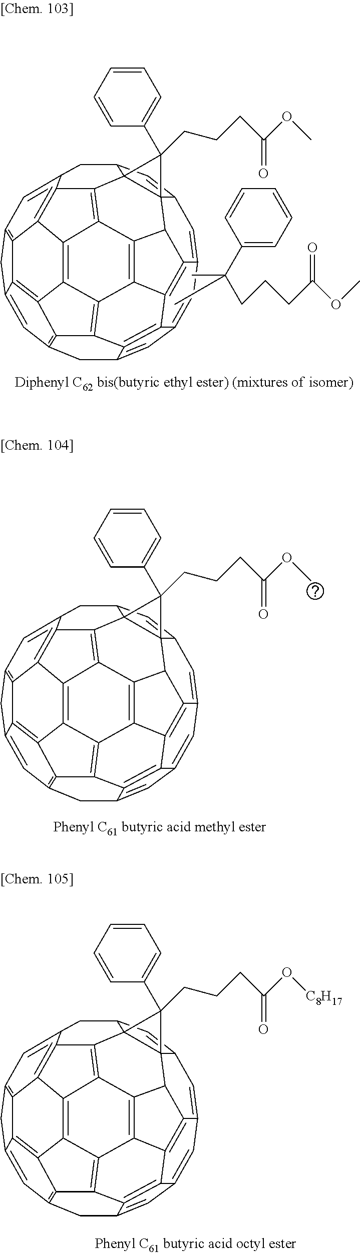

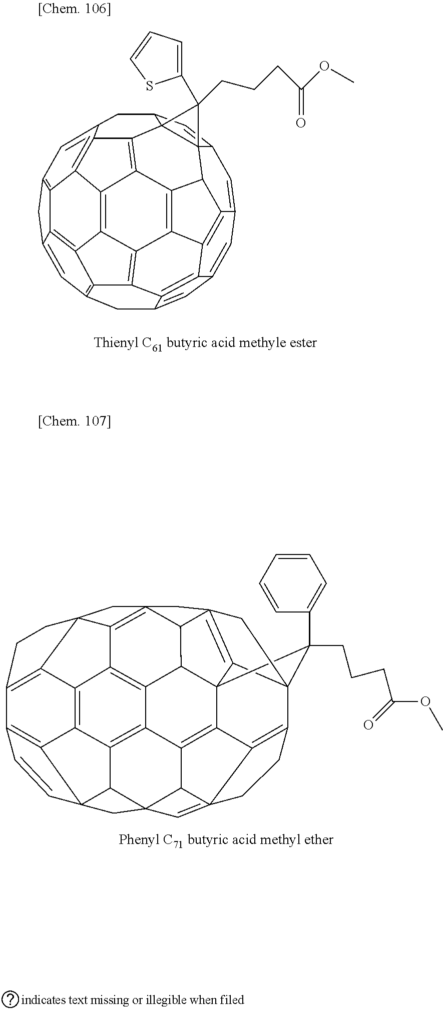

The graphene layer for forming the secondary battery plus electrode face 50 in the photoelectric conversion element 70 having storage/discharge ability is a single layer of carbon atom, and it is difficult to form a homogeneous graphene layer, so that a graphite layer wherein at least a part of the graphene layer becomes a multilayer may be used. Further, a layer made of carbon nanotube (CNT) that is a tube formed of continuous carbon atoms may be used. In particular, the layer containing carbon is preferably a graphene layer formed of a carbon single layer. Therefore, the mean thickness of the layer containing carbon is usually in the range of 0.01 to 10 nm. The graphene layer has only to be formed on at least a part of the surface of a secondary plus electrode 50. Although the graphene layer is preferably formed all over the surface, the whole surface of the secondary battery electrolyte layer 48 does not necessarily have to be coated with the graphene layer because the graphene layer is a carbon single layer.

On a surface of such a secondary battery plus electrode face 50 where the second electrolyte layer 48 is not formed, a secondary battery plus electrode 22 is formed.

The secondary battery plus electrode 22 is formed of a copper or pure copper powder deposit, and a bump 68 is formed at the position corresponding to the pump 66 formed on the aforesaid p-type compound semiconductor layer 18. At the opposite end to the end at which the pump 68 is formed, a plus electrode terminal 64 is formed. The bump 66 and the bump 68 are made connectable to each other with a conductor wire 69 such as a copper wire.

Accordingly, if the p-type compound semiconductor layer 18 and the plus electrode 22 are connected through the conductor wire 69, a positive hole is transferred to the plus electrode 22, and a potential difference is produced between the plus electrode terminal 64 of the plus electrode 22 and the minus electrode terminal 62 derived from the substrate layer 12.

The n-type compound semiconductor layer 16 formed from the dielectric composition prepared as above contains at least a fullerene, a conductive polymer and an organic dye, and when the n-type compound semiconductor layer 16 is irradiated with light, the light is absorbed by the organic pigment to bring about charge separation in the conductive polymer, as shown by, for example, the following formula, and an electron excited and released reaches the fullerene and then reaches the substrate layer through the collector electrode 14 to negatively charge the substrate layer 16.

When the plus electrode terminal 64 is connected to the minus electrode terminal 62 through a resistance, a positive hole generated in the p-type compound semiconductor layer 18 and an electron generated in the n-type compound semiconductor layer 16 flow in the circuit to bring about positive charge transfer and charge recombination in the n-type compound semiconductor layer, as shown below, whereby the excited organic pigment is returned to its original state.

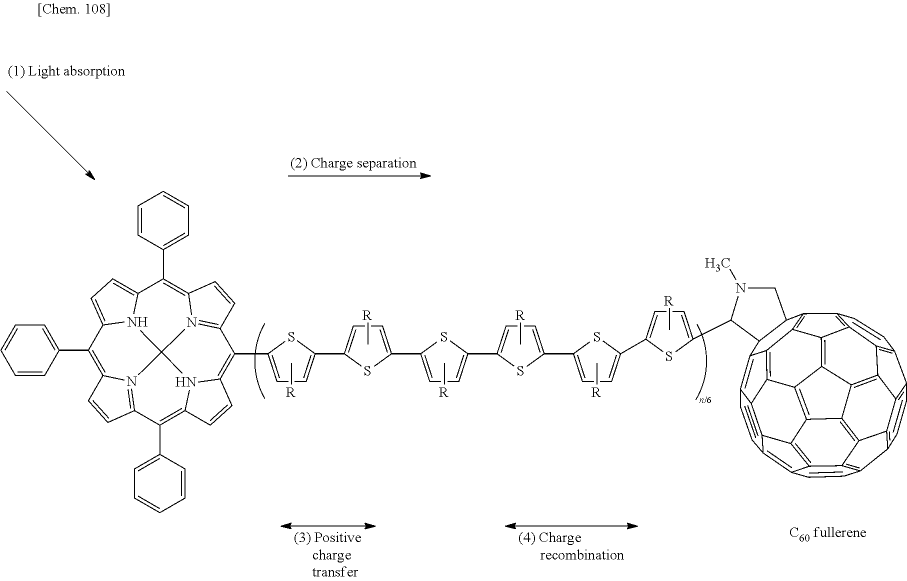

In the above formula, n is an integer of 1 to 600, and R represents a hydrocarbon group. As a matter of course, the part of the organic pigment in the above formula may be an organic pigment such as phthalocyanine, benzoporphyrin, quinacridone or pyrrolopyrrole, or a precursor of the organic pigment.

Current flows as above, and as a result, a difference in temperature occurs between the front surface and the back surface of a cell of the photoelectric conversion element of the present invention. This difference in temperature allows the photoelectric conversion element to generate electromotive force by virtue of Seebeck effect, and in the present invention, therefore, electromotive force attributable to the Seebeck effect can be also utilized.

Next, examples of synthesis of polyaniline using, as a base, polyanilinesulfonic acid obtained by modifying polyaniline (PANI) that is a conductive polymer with sulfonic acid group (—SO₃H), synthesis of a material carried out simultaneously with modification with sulfonic acid group, and preparation of a p-type semiconductor are shown below.

### Example 1

### First Step

In an Erlenmeyer flask having a volume of 300 ml, 50 ml of toluene (C₆H₅CH₃, molecular weight: 92.14) was placed, and 22.2 g of di-2-ethylhexyl sodium sulfosuccinate (C₂₀H₃₇NaO₇S, molecular weight: 444.56) was placed therein. The flask was sealed with a rubber stopper to block the outside air, and the contents in the flask were stirred for 10 minutes to completely dissolve di-n-ethylhexyl sodium sulfosuccinate in toluene.

### Second Step

To the toluene solution obtained in the first step, 20 ml of aniline (C₆H₇N, molecular weight: 93.13) was added, and they were stirred for 5 minutes until the mixture became a homogeneous light yellow solution.

### Third Step

To 180 ml of pure water (H₂O) was added 20 ml of hydrochloric acid (37% aqueous solution of HCl) to prepare 200 ml of a hydrochloric acid aqueous solution. While stirring the light yellow solution obtained in the second step by a magnetic stirrer, 150 ml of the above-prepared hydrochloric acid aqueous solution was slowly added to the light yellow solution, and they were sufficiently stirred to give a light yellow turbid liquid containing a cloudy substance. In the case of insufficient stirring, the yield of polyaniline (PANI) is lowered.

### Fourth Step

To 50 ml of the residue of the hydrochloric acid aqueous solution prepared in the third step, 2.7 g of ammonium peroxodisulfate ((NH₄)₂S₂O₈, molecular weight: 228.20) was slowly added while stirring, and stirring was continued for 20 minutes until particles of ammonium peroxodisulfate were completely dissolved, whereby a hydrochloric acid aqueous solution of ammonium peroxodisulfate was prepared.

### Fifth Step

To the light yellow turbid liquid containing a cloudy substance prepared in the third step, the hydrochloric acid aqueous solution of ammonium peroxodisulfate prepared in the fourth step was dropwise added by 0.5 to 1 droplet per second while stirring at 120 rpm, to carry out polymerization reaction.

Also after completion of dropwise addition of the hydrochloric acid aqueous solution of ammonium peroxodisulfate, stirring was continued for 20 hours, whereby the polymerization reaction proceeded, and the unreacted product (dark brown or red) residue was minimized.

The reaction temperature of the above reaction is not higher than 30° C., preferably not higher than 20° C., particularly preferably 10 to 15° C. If the reaction temperature exceeds 34° C., gelation rapidly proceeds, and smooth stirring cannot be carried out, so that homogenous reaction cannot be carried out.

### Sixth Step

The reaction liquid obtained in the fifth step was allowed to stand in an environment of room temperature (15 to 20° C.) and a humidity of 50%, and after 8 to 10 hours, the reaction liquid underwent phase separation into an oil phase consisting of PANI and toluene that was a solvent and a phase of the hydrochloric acid aqueous solution used in the polymerization reaction. The aqueous phase was removed by the use of a separatory funnel.

The resulting oil phase was washed five times with water having a temperature of 10 to 15° C.

In this washing, a 1M hydrochloric acid aqueous solution can be used instead of water, and in this case, the washing temperature is preferably 10 to 15° C. If hot water of 30° C. is used, the toluene solution containing PANI also sometimes flows out, and the yield of PANI after washing is lowered.

### Seventh Step

The toluene solution of PANI, washing of which had been completed in the sixth step and from which the water content had been separated, was transferred into a Petri dish and placed under an intake device having a solvent recovery function, and toluene was evaporated and recovered by the recovery device. PANI obtained by removing toluene as above was dried under the non-heating conditions, and the resulting aggregate was pulverized to obtain powdery PANI.

In this connection, the drying rate of the PANI aggregate obtained by removing toluene is enhanced by introducing dry air and carrying out exhaustion with a vacuum pump.

Solubilities of the resulting PANI in organic solvents are set forth in Table 1.

TABLE 1

| | Solvent type | | | |
|---|---|---|---|---|
| | N-Methyl-2- | | | |
| | pyrrolidone | Acetone | Toluene | m-Cresol |
| Mass ratio of soluble | 50-60 | 30-40 | 50-65 | 20-45 |
| matter to solvent (%) | | | | |

The drying time in the case of using the above solvents is set forth in Table 2.

TABLE 2

Solvent type

| | N-Methyl-2- | | | |
|---|---|---|---|---|
| | pyrrolidone | Acetone | Toluene | m-Cresol |
| Drying time | 5-15 | 1.5-5 | 2-10 | 4-12 |
| (minute(s)) | | | | |

Production of Photoelectric Conversion Element

Using polyaniline polyaniline (PANI) prepared) prepared as above, such a photoelectric conversion element (solar battery) as shown in FIG. 6 was produced as described below.

Step I

On a front surface of a quartz glass 7 of 18 mm×18 mm functioning as a substrate, copper is sputter-deposited in a film thickness of 100 to 500 nm to form a collector electrode (copper)) 6 made of copper.

Step II

At the central part of the quarts glass 7 on which copper had been sputter-deposited, a window of 5 mm×5 mm was formed, and masking of the quarts glass with a polyimide film having heat resistance was carried out so that the window might be exposed.

Step III

The substrate obtained in the step II was placed on a hot plate and heated to 100 to 150° C., then a coating liquid obtained by adding graphene to the toluene solution of PANI obtained in the aforesaid seventh step was applied by casting in a dry thickness of 100 nm to 500 nm to form a film. Thus, a p-type organic semiconductor material layer was formed. In FIG. 8, an SEM photograph of p-type semiconductor polymer material (polyaniline, graphene) particles is shown. The magnifications are 20000.

Step IV

A pn-bulk layer 4 (main component:strontium titanate) was formed by casting under the same conditions as in the step III. The film thickness was 10 to 50 nm.

Step V

On a surface of the pn-bulk layer formed in the step IV, an n-type organic semiconductor layer 3 having a thickness of 100 to 500 nm was formed by casting under the same conditions as above. The n-type organic semiconductor layer 3 was prepared using fullerene, phthalocyanine (H₂Pc), graphene and molybdenum oxide. In FIG. 9, an SEM photograph of the n-type nanocarbon material (C₆₀ fullerene, graphene, H₂Pc (phthalocyanine), molybdenumoxide) particles is shown. The magnifications are 40000.

Step VI

The temperature of the hot plate was adjusted to 40 to 50° C., and a buffer (BCP) 2 was formed on a surface of the n-type organic semiconductor layer 3 by casting. The thickness of the buffer bathocuproine (BCP) 2 was 5 nm to 15 nm.

Step VII

The mask on one side of the substrate of 18 mm×18 mm formed as above was peeled off, then a new heat-resistant polyimide tape was applied again, and thereafter, aluminum was sputter-deposited in a thickness of 100 to 500 nm on the whole surface of the quarts glass to form a collector electrode (aluminum) 1. This collector electrode (aluminum) 1 becomes a negative electrode of this power generation element.

Step VIII

Leaving the heat-resistant polyimide tape having been newly applied as above, the heat-resistant polyimide tape on other three sides of the substrate was peeled off to expose the collector electrode (copper) 1 made of copper having been sputter-deposited first. The collector electrode (copper) 6 becomes a positive electrode of this power generation element.

Step IX

The collector electrode (copper) 6 exposed as above was coated with a conductive paste (trade name: Dotite, available from Fujikura Kasei Co., Ltd.), and a copper fine wire was derived to give a positive electrode. Similarly, the collector electrode (aluminum) 1 was coated with a conductive paste, and a copper fine wire was derived to give a negative electrode.

Step X

The positive electrode and the negative electrode derived as above were connected to electrodes of an oscilloscope, respectively, and thermoelectromagnetic waves were allowed to enter the quartz glass on the lower surface side in FIG. 6 to measure power generation quantity.

That is to say, the power generation quantity of the photoelectric conversion element formed as above was measured.

In FIG. 7, an IV curve of a 5 mm×5 mm cell produced in the same manner as above is shown.

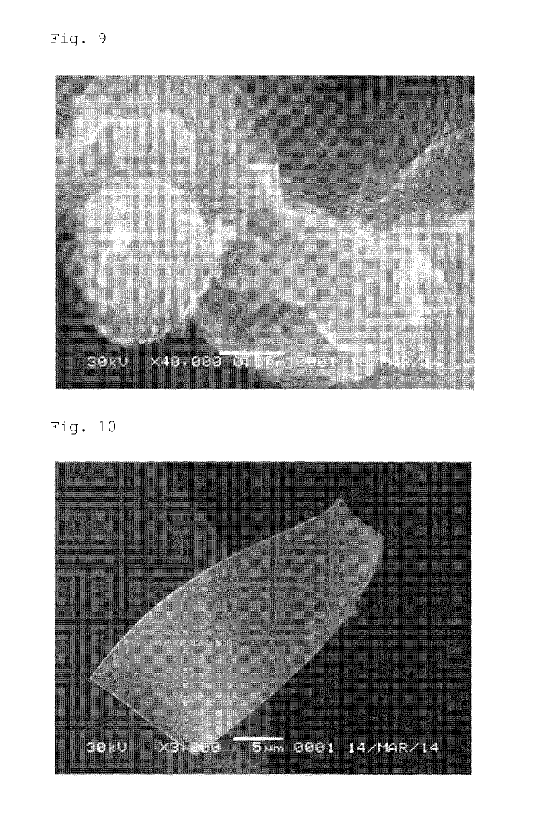

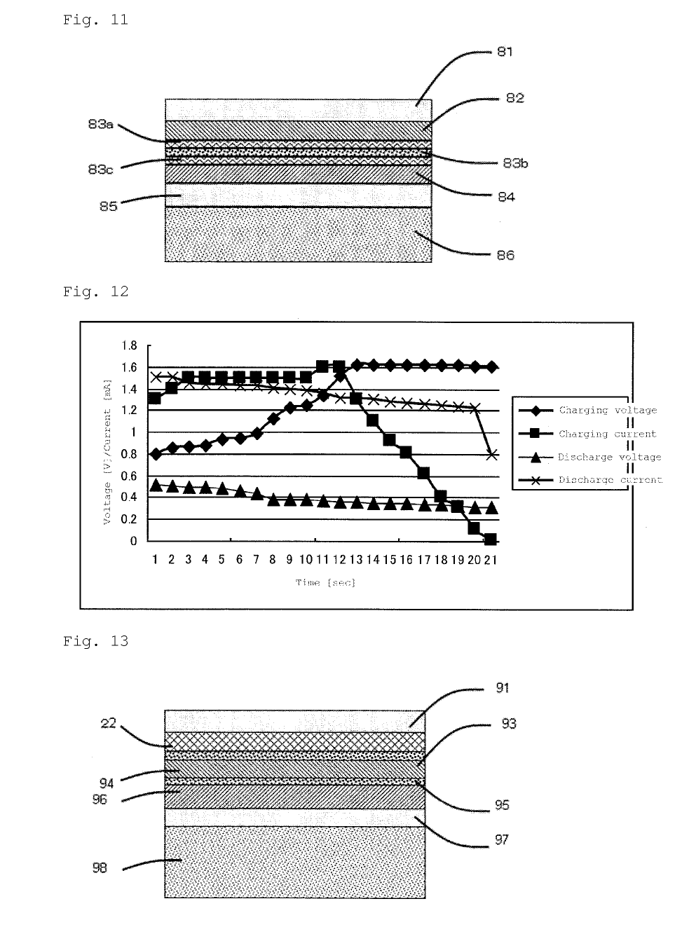

In FIG. 10, an example of an SEM photograph of a graphene sheet that was a conductive assistant used in the p-type organic semiconductor layer and the n-type organic semiconductor layer is shown. This graphene sheet has a maximum size of 40 μm (width)×120 μm (height). The magnifications of the SEM photograph in FIG. 10 are 3000.

The photoelectric conversion element of the present invention has extremely high optical energy-electrical energy conversion efficiency, and for example, the electromotive force given when a pixel of 0.5 mm² is irradiated is in the range of 2.3 mV to 3.8 mV. In usual, one cell of a solar battery consists of about 50 pixels connected in series, and therefore, the electromotive force of one cell of the solar battery of the present invention becomes as follows.

0.0023 V×50 pixels=0.115 V

0.0038 V×50 pixels=0.19 V

The electromotive force per pixel in the present example was 3.5 mV, so that the electromotive force of one cell (25 mm²) of the solar battery in the present example is as follows.

0.0035 V×50 pixels=0.175 V

Most of solar batteries are each formed of one cell unit in which 100 of such cells as above are connected in series, and therefore, the voltage generated in this one cell unit is as follows.

0.115 V×100 cells=11.5 V

0.19 V×100 cells=19 V

If the value of current that flows therein is 0.001 A, the power generated by the cell unit is as follows.

11.5 V×0.001 A=0.0115 W=11.5 mW

19 V×0.001 A=0.019 W=19 mW.

In the present example, the power becomes as follows.

17.5 V×0.001 A=0.0175 W=17.5 mW.

In the solar battery mounted, a panel of 60 mm×95 mm in which 228 cells each having a size of 5 mm (width)×5 mm (length)=25 mm² are connected in parallel is used, and such a panel can supply the following power.

11.5 mW×228 cells=2.62 W

19 mW×228 cells=4.33 W

In the case of a solar battery (1000 mm×1000 mm=1 m²) widely used, the area of this solar battery is 40000 times the area (25 mm²) of the above-mentioned cell, and therefore, the following power is obtained.

11.5 mW×40000=460 W=0.46 kW

19 mW×40000=760 W=0.76 kW

In the present example, the following power was obtained.

17.5 mW×40000=700 W=0.7 kW

The energy of light applied in order to obtain such electrical energy as above could be converted into electrical energy with high conversion efficiency.

With regard to the photoelectric conversion element having storage/discharge ability in which a photoelectric conversion element is combined with a secondary battery as above, power can be supplied from the secondary battery arranged on the back surface even in circumstances where the photoelectric conversion element is not irradiated with light.

Further, even if a trouble occurs in the photoelectric conversion element of the present invention, it is enough just to replace only a cell having a trouble, and the whole panel does not need to be replaced.

Furthermore, the photoelectric conversion element of the present invention can be formed by using a material of high flexibility without using a material having no flexibility, such as glass, and therefore, flexibility can be imparted to the photoelectric conversion element of the present invention. Hence, the photoelectric conversion element of the present invention can be arranged on not only a plane surface but also a curved surface.

Moreover, since the photoelectric conversion element of the present invention has good flexibility and is extremely thin, it can be mass-produced by a roll-to-roll method.

In addition, with regard to the fullerenes for use in the present invention, a process for producing them by steam-baking materials derived from vegetables, such as chaff, in the absence of oxygen has been practically used recently, and the fullerenes that were expensive in the past have been gradually becoming inexpensive, so that an environment in which the photoelectric conversion element of the present invention can be inexpensively provided is being arranged.

When a secondary battery is used by being incorporated, a water-insoluble ionic liquid is used as an electrolyte of the secondary battery, and therefore, a housing or the like is not eroded by the electrolyte. Further, since driving of the secondary battery is not attended with chemical reaction, a component due to chemical reaction, such as water or a gas, is not formed, and therefore, the secondary battery has extremely high safety.

An IV curve of the photoelectric conversion element (5 mm×5 mm) of the present invention is shown in FIG. 7.

The measuring conditions, etc. are as follows.

TABLE 3
1. Evaluation conditions
<Evaluation device>
Electronic load device (variable resistance + MOS − FET)
<Evaluation conditions>

| | |
|---|---|
| Measuring temperature | 21.5° C., 28% |
| Measurement mode | constant voltage |

2. Measurement results

| Voltage (V) | Current (mA) | Power (mW) | |
|---|---|---|---|
| 0.31 | 1.6 | 0.496 | |
| 0.32 | 1.6 | 0.512 | |
| 0.35 | 1.62 | 0.567 | |
| 0.38 | 1.63 | 0.6194 | |
| 0.39 | 1.64 | 0.6396 | |
| 0.41 | 1.65 | 0.6765 | |
| 0.43 | 1.66 | 0.7138 | |
| 0.44 | 1.68 | 0.7392 | |
| 0.48 | 1.7 | 0.816 | |
| 0.49 | 1.6 | 0.784 | |
| 0.5 | 1.2 | 0.6 | |
| 0.6 | 0.9 | 0.54 | |
| 0.7 | 0.6 | 0.42 | |
| 0.8 | 0.5 | 0.4 | |
| 0.9 | 0.3 | 0.27 | |
| 1.1 | 0.1 | 0.11 | |
| 1.2 | 0 | 0 | Open circuit voltage (Voc) |

### Example 2

Example of production of storage element (secondary battery) in which layer of ferroelectric substance (strontium titanate or the like) coated with ion adsorption substance such as graphene and layer of ion supply substance (e.g., alkali metal salt bonded to graphene) are arranged interposing therebetween solid electrolyte such as vanadate and which utilizes adsorption of ion molecule and charge accumulation of ferroelectric

Step i

A quartz cover glass of 18 mm×18 mm was used as a substrate 86, and on the whole surface of the substrate 86, sputtering was carried out using pure copper as a target to form a sputtered film having a thickness of 100 nm to 500 nm. This sputtered film (copper) becomes a collector electrode (copper) 85 and also becomes an electrode.

Step ii

On a surface of the copper sputtered film formed in the step i, a heat-resistant polyimide tape was applied in such a manner that an opening of 5 mm×5 mm was formed, whereby masking was carried out.

Step iii

From alkali metal salts, potassium chloride was selected as an ion supply substance, and in an agate mortar, graphene powder and potassium chloride were ground in a solid phase for not shorter than 1 hour. The resulting powder was dispersed in N-methyl-2-pyrrolidone (NMP) to prepare a casting liquid, and the casting liquid was applied to the opening of 5 mm×5 mm formed in the step ii to form an ion supply substance layer 83c. The thickness of the ion supply substance layer 83c was 100 nm to 500 nm.

The potential of the storage layer varies as follows depending upon the potential window of the alkali metal used.

Potassium (K): −2.925 V

Sodium (Na): −2.714 V

Lithium (Li): −3.045 V

Step iv

An ion conductive substance of an amorphous structure containing vanadate as a main agent and functioning as a solid electrolyte was kneaded with paraffin oil functioning as an adhesive to prepare a paste, and using the paste, a film was formed by a push coating method. Thus, a solid electrolyte layer 83b was formed. The thickness of this solid electrolyte film was 50 nm to 100 nm.

Step v

Using strontium titanate that was a ferroelectric and graphene as an ion adsorption substance, mixing/synthesis was carried out by a mechanochemical method, and the mixture was dispersed in N-methyl-2-pyrrolidone (NMP) to prepare a casting liquid. The casting liquid was cast on the solid electrolyte layer 83b to form a ferroelectric layer 83a. The thickness of the ferroelectric layer 83a was 100 nm to 500 nm.

Step vi

The heat-resistant polyimide tape on one side of the substrate 86, said tape having been applied to the surface of the substrate, was peeled off, and a new heat-resistant polyimide tape was applied again. On the whole surface of the substrate 86, sputtering was carried out using aluminum as a target to form a collector electrode (aluminum) 81. The thickness of the collector electrode (aluminum) 81 was 100 nm to 500 nm and was an electrode.

Step vii

Leaving the heat-resistant polyimide film newly applied in the step vi, the heat-resistant polyimide tape on other three sides of the substrate was peeled off to expose the collector electrode (copper) 85 formed of the sputtered film (copper). This collector electrode (copper) 85 becomes a positive electrode in the secondary battery of the present invention. The collector electrode (aluminum) 81 formed in the step vi becomes a negative electrode in the secondary battery of the present invention.

Step viii

The collector electrode (copper) 86 exposed as above was coated with a conductive paste (trade name: Dotite, available from Fujikura Kasei Co., Ltd.), and a copper fine wire was derived to give a positive electrode. Similarly, the collector electrode (aluminum) 81 was coated with a conductive paste, and a copper fine wire was derived to give a negative electrode. Then, charge/discharge properties were measured.

The test was carried out by a constant-voltage constant-current charging method.

The measuring conditions are as follows.

Charging voltage=1.6 V

Charging current=1.5 mA

Load resistance during discharge=100 Ω±5%

The results are shown in Table 4 and in FIG. 12.

TABLE 4

| | Charging | Charging | Discharge | Discharge |
|---|---|---|---|---|
| Time | voltage | current | voltage | current |
| (sec) | (V) | (mA) | (V) | (mA) |
| 0 | 0.8 | 1.3 | 0.52 | 1.51 |
| 1 | 0.85 | 1.4 | 0.51 | 1.51 |
| 2 | 0.87 | 1.5 | 0.5 | 1.45 |
| 3 | 0.88 | 1.5 | 0.49 | 1.44 |
| 4 | 0.93 | 1.5 | 0.48 | 1.44 |
| 5 | 0.95 | 1.5 | 0.46 | 1.43 |
| 6 | 0.99 | 1.5 | 0.44 | 1.43 |
| 7 | 1.12 | 1.5 | 0.38 | 1.41 |
| 8 | 1.23 | 1.5 | 0.38 | 1.39 |
| 9 | 1.25 | 1.5 | 0.38 | 1.38 |
| 10 | 1.34 | 1.6 | 0.37 | 1.36 |
| 11 | 1.52 | 1.6 | 0.36 | 1.32 |
| 12 | 1.62 | 1.3 | 0.36 | 1.32 |
| 13 | 1.62 | 1.1 | 0.35 | 1.31 |
| 14 | 1.62 | 0.92 | 0.35 | 1.28 |
| 15 | 1.62 | 0.81 | 0.35 | 1.27 |
| 16 | 1.62 | 0.62 | 0.34 | 1.26 |
| 17 | 1.62 | 0.41 | 0.34 | 1.25 |
| 18 | 1.62 | 0.32 | 0.33 | 1.24 |
| 19 | 1.61 | 0.11 | 0.32 | 1.23 |
| 20 | 1.61 | 0.01 | 0.31 | 0.8 |

By arranging the secondary battery obtained as above on the back surface of the photoelectric conversion element produced in Example 1, a photoelectric conversion element having storage/discharge ability could be produced.

### Example 3

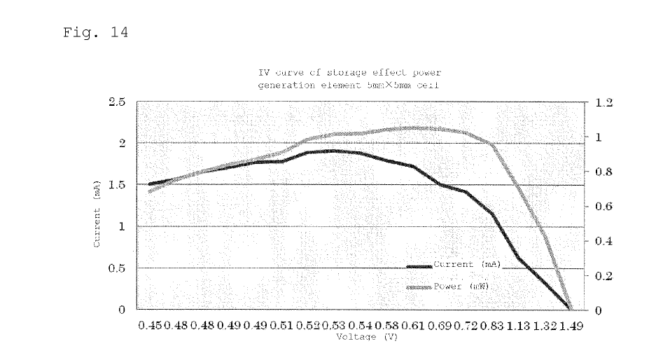

Example of photoelectric conversion element having storage effect in which power generation layer and power storage layer are combined as shown in FIG. 13

Step a

A quartz cover glass of 18 mm×18 mm was used as a substrate 98, and on the whole surface of the substrate 98, sputtering was carried out using pure copper as a target to form a sputtered film having a thickness of 100 nm to 500 nm. This sputtered film (copper) becomes a collector electrode (copper) 97 and also becomes an electrode.

Step b

On a surface of the copper sputtered film formed in the step a, a heat-resistant polyimide tape was applied in such a manner that an opening of 5 mm×5 mm was formed, whereby masking was carried out.

Step c

The substrate obtained in the step (b) was heated to 100 to 150° C., and a p-type organic semiconductor was casted to form a film. The thickness of this p-type organic semiconductor layer 96 was 100 to 500 nm.

Step d

A pn-bulk layer material was casted under the same conditions as in the step c to form a film. Thus, a pn-bulk layer 95 was formed. The thickness of this layer was 10 to 50 nm.

Step e

In an alumina mortar or an agate mortar, an n-type organic semiconductor material, potassium chloride selected from alkali metal salts as an ion supply substance and graphene powder were ground in a solid phase for not shorter than 1 hour. The resulting powder was dispersed in N-methyl-2-pyrrolidone (NMP), and the resulting dispersion was applied by a casting method to form an n-type organic semiconductor layer 94. The thickness of the layer was 100 nm to 500 nm.

Step f

An ion conductive substance of an amorphous structure containing vanadate as a main agent and functioning as a solid electrolyte was kneaded with paraffin oil functioning as an adhesive to prepare a paste, and using the paste, a film was formed by a push coating method. Thus, a solid electrolyte layer 93 was formed. The thickness of this solid electrolyte film was 50 nm to 100 nm.

Step g

Using strontium titanate that was a ferroelectric and graphene as an ion adsorption substance, mixing/synthesis was carried out by a mechanochemical method, and the mixture was dispersed in N-methyl-2-pyrrolidone (NMP) to prepare a casting liquid. The casting liquid was cast on the solid electrolyte layer 92 to forma ferroelectric layer 92a. The thickness of the ferroelectric layer 92 was 100 nm to 500 nm.

Step h

The heat-resistant polyimide tape on one side of the substrate, said tape having been applied to the surface of the substrate, was peeled off, and a new heat-resistant polyimide tape was applied again. On the whole surface of the substrate, sputtering was carried out using aluminum as a target to form a collector electrode (aluminum) 91. The thickness of the collector electrode (aluminum) 91 was 100 nm to 500 nm and was an electrode.

Step i

Leaving the heat-resistant polyimide film newly applied in the step h, the heat-resistant polyimide tape on other three sides of the substrate was peeled off to expose the collector electrode (copper) 98 formed of the sputtered film (copper). This collector electrode (copper) 85 becomes a positive electrode in the secondary battery of the present invention. The collector electrode (aluminum) 91 formed in the step a becomes a negative electrode in the secondary battery of the present invention.

Step k

The collector electrode (copper) 98 exposed as above was coated with a conductive paste (trade name: Dotite, available from Fujikura Kasei Co., Ltd.), and a copper fine wire was derived to give a negative electrode. Similarly, the collector electrode (aluminum) 91 was coated with a conductive paste, and a copper fine wire was derived to give a positive electrode. Then, charge/discharge properties were measured.

The test was carried out by a constant-voltage constant-current charging method.

The measuring conditions are as follows.

Charging voltage=1.6 V

Charging current=1.5 mA

Load resistance during discharge=100 Ω±5%

The results are shown in FIG. 14.

### REFERENCE SIGNS LIST

1: collector electrode (aluminum)
2: buffer (BCP)
3: n-type organic semiconductor
4: pn-bulk layer
5: p-type organic semiconductor (polyaniline thin film)
6: collector electrode (copper)
7: substrate (quartz glass)
10: photoelectric conversion element
11: plus electrode
12: substrate layer
14: collector electrode
16: n-type compound semiconductor layer
18: p-type compound semiconductor layer
20: pn-bulk compound semiconductor layer
22: secondary battery plus electrode
24: surface protective layer
42: secondary battery minus electrode face
44: ferroelectric layer (first electrolyte layer)
46: solid electrolyte layer
48: ion supply substance layer (ion supply substance layer)
50: secondary battery plus electrode face
52a, 62b: insulating layer
62: minus electrode terminal
64: plus electrode terminal
69: conductor wire
70: photoelectric conversion element having storage/discharge ability
80: secondary battery
81: collector electrode (aluminum)
82: secondary battery minus electrode face
83a: ferroelectric layer
83b: solid electrolyte layer
83c: ion supply substance layer
84: secondary battery plus electrode face
85: collector electrode (copper) (substrate layer)
86: substrate (quartz glass)
91: collector electrode (aluminum)
92: ferroelectric layer (strontium titanate+graphene+molybdenum oxide)
93: solid electrolyte layer (containing vanadate)
94: n-type organic semiconductor [(fullerene, phthalocyanine, graphene, molybdenum oxide)+ion supply substance (graphene+alkali metal salt)]
95: pn-bulk layer
96: p-type organic semiconductor layer (polyaniline thin film)
97: collector electrode (copper)
98: substrate (quartz glass)

1. A photoelectric conversion element having a substrate layer that is formed of a conductive metal and is connected to a minus electrode of output electrodes, a collector electrode that is formed by being joined to one surface of the substrate layer, an n-type compound semiconductor layer that is formed of a dielectric composition containing a fullerene and is formed by being connected to the collector electrode, a p-type compound semiconductor layer that is formed in contact with the n-type compound semiconductor layer, a pn-bulk layer that is formed between the n-type compound semiconductor layer and the p-type compound semiconductor layer and is intermittently in contact with the n-type compound semiconductor layer and the p-type compound semiconductor layer, and a plus electrode that is formed on the other surface of the substrate layer through an insulating layer, wherein the plus electrode is insulated from the collector electrode, the pn-bulk layer and the n-type compound semiconductor layer but is electrically connected to the p-type compound semiconductor layer.

2. The photoelectric conversion element as claimed in claim 1, wherein the n-type compound semiconductor layer is formed on a surface of the collector electrode through at least one layer selected from the group consisting of a graphene layer, a graphite layer and a carbon nanotube layer.

3. The photoelectric conversion element as claimed in claim 1, wherein the dielectric composition containing a fullerene and forming the n-type compound semiconductor layer contains at least C₆₀ fullerene and/or C₇₀ fullerene, a conductive polymer and an organic pigment, and at least a part of them are bonded to one another to make electron transfer in the n-type compound semiconductor layer possible.

4. The photoelectric conversion element as claimed in claim 1, wherein at least a part of the fullerene that forms the n-type compound semiconductor layer is contained in the n-type compound semiconductor layer in such a manner that it is capable of molecular rotation.

5. The photoelectric conversion element as claimed in claim 1, wherein the p-type compound semiconductor layer is a transparent evaporated film formed from an oxide comprising silicon dioxide containing a dopant that forms a positive hole.

6. The photoelectric conversion element as claimed in claim 1, wherein the substrate layer is formed from copper.

7. The photoelectric conversion element as claimed in claim 1, wherein the collector electrode is formed of a metallic aluminum evaporated layer.

8. The photoelectric conversion element as claimed in claim 1, wherein the pn-bulk layer is a ferroelectric layer containing at least one dielectric selected from the group consisting of lead titanate, lead(II) zirconate titanate and strontium titanate.

9. The photoelectric conversion element as claimed in claim 1, wherein the fullerene is at least one fullerene selected from the group consisting of C₆₀, C₆₂, C₆₈, C₇₀, C₈₀, C₈₂ and carbon nanotube (CNT), or any of the fullerenes, which has been doped or intercalated with an alkali metal and/or an alkaline earth metal, or any of the fullerenes, which includes a metal.

10. The photoelectric conversion element as claimed in claim 1, wherein the fullerene contained in the n-type compound semiconductor layer is in contact with the pn-bulk layer while vibrating, and the photoelectric conversion element utilizes also electromotive force generated by a piezoelectric effect due to the vibration contact with the pn-bulk layer.

11. The photoelectric conversion element as claimed in claim 1, which utilizes also electromotive force generated by a Seebeck effect attributable to a difference in temperature between the negative electrode on a panel front surface and the positive electrode on a panel back surface.

12. A photoelectric conversion element having storage/discharge ability, said element having a substrate layer that is formed of a conductive metal and is connected to a minus electrode of output electrodes, a collector electrode that is formed by being joined to one surface of the substrate layer, an n-type compound semiconductor layer that is formed of a dielectric composition containing a fullerene and is formed by being connected to the collector electrode, a p-type compound semiconductor layer that is formed in contact with the n-type compound semiconductor layer, and a pn-bulk layer that is formed between the n-type compound semiconductor layer and the p-type compound semiconductor layer and is intermittently in contact with the n-type compound semiconductor layer and the p-type compound semiconductor layer, wherein
a secondary battery is arranged on the other surface of the substrate layer,
the secondary battery is formed while including the collector electrode and the substrate layer, and has a secondary battery minus electrode face laminated on the other surface of the substrate layer, said secondary battery minus electrode face being formed if necessary, a ferroelectric layer laminated on the secondary battery minus electrode face, a solid electrolyte layer, an ion supply substance layer formed through the solid electrolyte layer, a secondary battery plus electrode face that is formed of at least one conductive material selected from the group consisting of C₆₀ fullerene, C₇₀ fullerene, graphene, graphite and carbon nanotube (CNT) and is laminated in contact with the ion supply substance layer, said secondary battery plus electrode face being formed if necessary, and a plus electrode of output electrodes of the secondary battery, said plus electrode being connected to the p-type compound semiconductor layer.

13. The photoelectric conversion element having storage/discharge ability as claimed in claim 12, wherein the ferroelectric layer and the ion supply substance layer contain an ion supply component.

14. The photoelectric conversion element having storage/discharge ability as claimed in claim 12, wherein the n-type compound semiconductor layer is formed on a surface of the collector electrode through at least one layer selected from the group consisting of a graphene layer, a graphite layer and a carbon nanotube layer.

15. The photoelectric conversion element having storage/discharge ability as claimed in claim 12, wherein the dielectric composition containing a fullerene and forming the n-type compound semiconductor layer contains at least C₆₀ fullerene and/or C₇₀ fullerene, a conductive polymer and an organic pigment, and at least a part of them are bonded to one another to make electron transfer in the n-type compound semiconductor layer possible.

16. The photoelectric conversion element having storage/discharge ability as claimed in claim 12, wherein at least a part of the fullerene that forms the n-type compound semiconductor layer is contained in the n-type compound semiconductor layer in such a manner that it is capable of molecular rotation.

17. The photoelectric conversion element having storage/discharge ability as claimed in claim 12, wherein the p-type compound semiconductor layer is a transparent evaporated film formed from an oxide comprising silicon dioxide containing a dopant that forms a positive hole.

18. The photoelectric conversion element having storage/discharge ability as claimed in claim 12, wherein the substrate layer is formed from copper.

19. The photoelectric conversion element having storage/discharge ability as claimed in claim 12, wherein the collector electrode is formed of a metallic aluminum evaporated layer.

20. The photoelectric conversion element having storage/discharge ability as claimed in claim 12, wherein the pn-bulk layer is a ferroelectric layer containing at least one dielectric selected from the group consisting of lead titanate, lead(II) zirconate titanate and strontium titanate.

21. The photoelectric conversion element having storage/discharge ability as claimed in claim 12, wherein the fullerene is at least one fullerene selected from the group consisting of C₆₀, C₆₂, C₆₈, C₇₀, C₈₀, C₈₂ and carbon nanotube (CNT), or any of the fullerenes, which has been doped or intercalated with an alkali metal and/or an alkaline earth metal, or any of the fullerenes, which includes a metal.

22. The photoelectric conversion element having storage/discharge ability as claimed in claim 12, wherein the fullerene contained in the n-type compound semiconductor layer is in contact with the pn-bulk layer while vibrating, and the photoelectric conversion element utilizes also electromotive force generated by a piezoelectric effect due to the vibration contact with the pn-bulk layer.

23. The photoelectric conversion element having storage/discharge ability as claimed in claim 12, which utilizes also electromotive force generated by a Seebeck effect attributable to a difference in temperature between the negative electrode on a panel front surface and the positive electrode on a panel back surface.

24. The photoelectric conversion element having storage/discharge ability as claimed in claim 12, wherein the secondary battery minus electrode face is formed of silicon dioxide doped with at least one atom selected from the group consisting of phosphorus, boron and fluorine.

25. The photoelectric conversion element having storage/discharge ability as claimed in claim 12, wherein the ferroelectric layer and the ion supply substance layer contain an ionic liquid, and the ionic liquid is at least one ionic liquid selected from the group consisting of 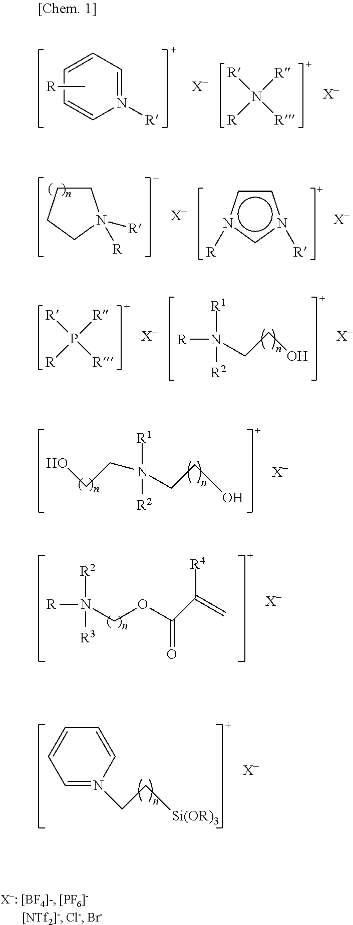
wherein R, R¹, R², R³, R′, R″ and R′″ each independently represent a hydrogen atom or an alkyl group, and each n independently represents an integer of 1 to 3.

26. A secondary battery comprising a secondary battery minus electrode face that is formed of a metal oxide comprising silicon dioxide and is laminated on one surface of a substrate layer having an evaporated collector electrode on the other surface, a ferroelectric layer that contains an ionic liquid electrolyte and is laminated on the secondary battery minus electrode face, a solid electrolyte layer, an ion supply substance layer that contains an ionic liquid electrolyte and is formed through the solid electrolyte layer, a secondary battery plus electrode face that is formed of at least one conductive material selected from the group consisting of C₆₀ fullerene, C₇₀ fullerene, graphene, graphite and carbon nanotube (CNT) and is laminated in contact with the ion supply substance layer, and a plus electrode that is arranged by being connected to the secondary battery plus electrode face, wherein a minus electrode terminal is derived from the substrate layer, and a plus electrode terminal is derived from the plus electrode.

27. The secondary battery as claimed in claim 26, wherein the ferroelectric layer and the ion supply substance layer each independently further contain at least one nonaqueous electrolyte selected from the group consisting of a cationic polymer electrolyte, an anion molecule electrolyte and a fullerene electrolyte.

28. The secondary battery as claimed in claim 26, wherein the substrate layer is formed from copper.

29. The secondary battery as claimed in claim 26, wherein the collector electrode is formed of a metallic aluminum evaporated layer.

30. The secondary battery as claimed in claim 26, wherein the fullerene is at least one fullerene selected from the group consisting of C₆₀, C₆₂, C₆₈, C₇₀, C₈₀, C₈₂ and carbon nanotube (CNT), or any of the fullerenes, which has been doped or intercalated with an alkali metal and/or an alkaline earth metal, or any of the fullerenes, which includes a metal.

31. The secondary battery as claimed in claim 26, wherein the solid electrolyte layer is a reverse osmosis membrane.

32. The secondary battery as claimed in claim 26, wherein the ion supply substance layer contains an ion supply substance, and the ionic liquid is at least one ionic liquid selected from the group consisting of 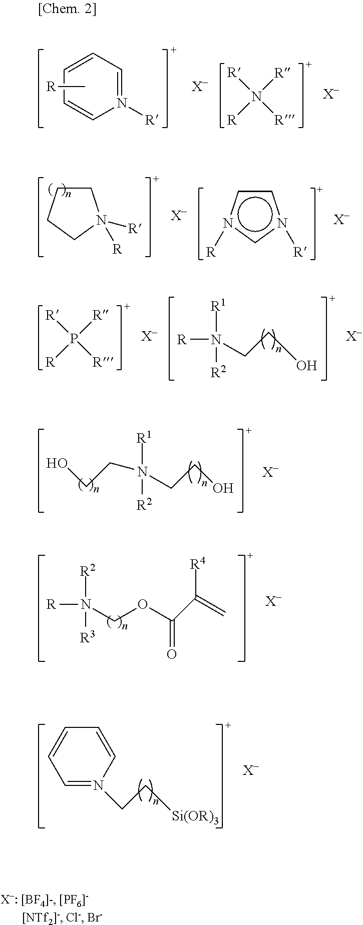
wherein R, R¹, R², R³, R′, R″ and R′″ each independently represent a hydrogen atom or an alkyl group, and each n independently represents an integer of 1 to 3.

33. The secondary battery as claimed in claim 26, wherein the ion supply substance is a halide of an alkali metal.
